(19) United States
(12) Patent Application Publication
(10) Pub. No.: US 2024/0157360 A1
(43) Pub. Date: May 16, 2024

(54) MICROFLUIDIC SUBSTRATE, MICROFLUIDIC DEVICE AND DRIVING METHOD THEREOF

(71) Applicant: Shanghai Tianma Micro-electronics Co., Ltd., Shanghai (CN)

(72) Inventors: Kaidi ZHANG, Shanghai (CN); Baiquan LIN, Shanghai (CN); Wei LI, Shanghai (CN); Yunfei BAI, Shanghai (CN); Linzhi WANG, Shanghai (CN); Yukun HUANG, Shanghai (CN); Kerui XI, Shanghai (CN)

(21) Appl. No.: 18/124,254

(22) Filed: Mar. 21, 2023

(30) Foreign Application Priority Data
Nov. 15, 2022 (CN) 202211429134.6

(51) Int. Cl. B01L 3/00

(52) U.S. Cl. CPC B01L 3/50273; B01L 2300/0645; B01L 2300/0654; B01L 2300/168; B01L 2400/0427

(57) ABSTRACT

Microfluidic substrate, microfluidic device, and driving method thereof are provided. The microfluidic substrate includes a plurality of detection units arranged in an array. A detection unit of the plurality of detection units at least includes a first switch transistor, a second switch transistor, a drive electrode, and a photosensitive element. The microfluid substrate includes a base; a transistor array layer on a side of the base, first switch transistors and second switch transistors being on the transistor array layer; a photosensitive element array layer on a side of the transistor array layer away from the substrate, photosensitive elements being on the photosensitive element array layer; a first electrode layer on a side of the photosensitive element array layer away from the base; and a second electrode layer on a side of the first electrode layer away from the base.

### CROSS-REFERENCE TO RELATED APPLICATION

This application claims priority of Chinese Patent Application No. 202211429134.6, filed on Nov. 15, 2022, the entire contents of which are hereby incorporated by reference.

### FIELD OF THE DISCLOSURE

The present disclosure generally relates to the field of microfluidic technology and, more particularly, relates to a microfluidic substrate, a microfluidic device, and a driving method thereof.

### BACKGROUND

Microfluidic technology is an emerging interdisciplinary technology involving chemistry, fluid physics, microelectronics, new material, biology, and biomedical engineering, which can achieve precise control and manipulation of tiny liquid droplets. Devices using microfluidic technology are generally called microfluidic chips, in which samples such as various cells can be cultured, moved, detected, and analyzed. Microfluidic technology not only has a wide range of applications in fields of chemistry and medicine, but also receives more and more attention in other fields. A mainstream driving method of microfluidic chips is an electrode driving based on electrowetting technology. A principle of the electrode driving is that a liquid droplet is placed on a surface with a lyophobic layer, with a help of an electrowetting effect, by supplying a voltage to the liquid droplet, a wettability between the liquid droplet and the lyophobic layer is changed, and a pressure difference and an asymmetric deformation are generated inside the liquid droplet, thereby achieving a directional movement of the liquid droplet.

An existing microfluidic technology uses an electrowetting principle to control a flow position of a tiny liquid droplet by setting a substrate voltage. The technology can be used in fields of biochemical analysis and detection, some of which are applied in a field of quantitative fluorescent polymerase chain reaction (PCR) and the like. While an optical detection of a liquid droplet is required to analyze a fluorescence intensity and corresponding droplet components, a real-time feedback of droplet position during a movement of the liquid droplet is required for precise control. However, current microfluidic chips are generally micron-sized detection chips, which are small in size. A single pixel unit not only needs to integrate a microfluidic structure for controlling a liquid droplet movement, but also needs to integrate an optical detection for analyzing a photoelectric detection structure of a fluorescence intensity. Therefore, to ensure a travel of the liquid droplet, an area left for a photoelectric detection structure on the single pixel unit is limited, especially for a pixel unit with a small area. The single pixel unit is difficult to achieve a high-precision photoelectric detection effect, resulting in a decrease in efficiency and accuracy of optical detection.

Therefore, it is a technical problem to be solved urgently by a person skilled in the art to provide a microfluidic substrate, a microfluidic device, and a driving method thereof that not only increase an area of a photoelectric detection structure in a single pixel to improve an efficiency and accuracy of an optical detection, but also avoid affecting a normal travel of a liquid droplet.

### BRIEF SUMMARY OF THE DISCLOSURE

One aspect of the present disclosure provides a microfluidic substrate. The microfluidic substrate includes a plurality of detection units arranged in an array. A detection unit of the plurality of detection units at least includes a first switch transistor, a second switch transistor, a drive electrode, and a photosensitive element. The microfluid substrate includes a base; a transistor array layer on a side of the base, first switch transistors and second switch transistors being on the transistor array layer; a photosensitive element array layer on a side of the transistor array layer away from the substrate, photosensitive elements being on the photosensitive element array layer, and the second switch transistors being electrically connected to a side of the photosensitive elements facing the base; a first electrode layer on a side of the photosensitive element array layer away from the base, the first electrode layer including a plurality of first electrode terminals electrically connected to a side of the photosensitive elements away from the base; and a second electrode layer on a side of the first electrode layer away from the base, drive electrodes being on the second electrode layer, and first switch transistors being electrically connected to the drive electrodes. The second electrode layer further includes a plurality of connection parts, in one detection unit of the plurality of detection units, a connection part of the plurality of connection parts is insulated from a drive electrode, and a first electrode terminal of the plurality of first electrode terminals is connected to a bias voltage part through the connection part. A film layer where the bias voltage part is located is on a side of the second electrode layer facing the base.

Another aspect of the present disclosure provides a microfluidic device. The microfluidic device includes a microfluidic substrate, a second substrate opposite to the microfluidic substrate, and a liquid droplet between the second substrate and the microfluidic substrate. The microfluidic substrate includes a plurality of detection units arranged in an array. A detection unit of the plurality of detection units at least includes a first switch transistor, a second switch transistor, a drive electrode, and a photosensitive element. The microfluid substrate includes a base; a transistor array layer on a side of the base, first switch transistors and second switch transistors being on the transistor array layer; a photosensitive element array layer on a side of the transistor array layer away from the substrate, photosensitive elements being on the photosensitive element array layer, and the second switch transistors being electrically connected to a side of the photosensitive elements facing the base; a first electrode layer on a side of the photosensitive element array layer away from the base, the first electrode layer including a plurality of first electrode terminals electrically connected to a side of the photosensitive elements away from the base; and a second electrode layer on a side of the first electrode layer away from the base, drive electrodes being on the second electrode layer, and first switch transistors being electrically connected to the drive electrodes. The second electrode layer further includes a plurality of connection parts, in one detection unit of the plurality of detection units, a connection part of the plurality of connection parts is insulated from a drive electrode, and a first electrode terminal of the plurality of first electrode terminals is connected to a bias voltage part through the connection part. A film layer where the bias voltage part is located is on a side of the second electrode layer facing the base.

Another aspect of the present disclosure provides a driving method of the microfluidic device. The driving method includes: turning on the first switch transistor corresponding to the detection unit in the (n−1)-th row, turning on the second switch transistor corresponding to the detection unit in the n-th row, and the photosensitive element detecting a liquid droplet at a corresponding position of the detection unit in the n-th row and the m-th column; sending a data voltage signal to the corresponding data line of the detection unit in the (n−1)-th row and the m-th column if the liquid droplet needs to move to a position of the detection unit in the (n−1)-th row and the m-th column, a driving electric field generated by the drive electrode at a corresponding position of the detection unit in the (n−1)-th row and the m-th column is greater than a driving electric field generated by the drive electrode at a corresponding position of the detection unit in the n-th row and the m-th column, the liquid droplet moving to a corresponding position of the detection unit in the (n−1)-th row and the m-th column; sending a data voltage signal to the corresponding data line of the detection unit in the (n+1)-th row and the m-th column if the liquid droplet needs to move to a position of the detection unit in the (n+1)-th row and the m-th column, a driving electric field generated by the drive electrode at a corresponding position of the detection unit in the (n+1)-th row and the m-th column is greater than a driving electric field generated by the drive electrode at a corresponding position of the detection unit in the n-th row and the m-th column, the liquid droplet moving to a corresponding position of the detection unit in the (n+1)-th row and the m-th column; sending a data voltage signal to the corresponding data line of the detection unit in the n-th row and the (m+1)-th column if the liquid droplet needs to move to a position of the detection unit in the n-th row and the (m+1)-th column, a driving electric field generated by the drive electrode at a corresponding position of the detection unit in the n-th row and the (m+1)-th column is greater than a driving electric field generated by the drive electrode at a corresponding position of the detection unit in the n-th row and the m-th column, the liquid droplet moving to a corresponding position of the detection unit in the n-th row and the (m+1)-th column; sending a data voltage signal to the corresponding data line of the detection unit in the n-th row and the (m−1)-th column if the liquid droplet needs to move to a position of the detection unit in the n-th row and the (m−1)-th column, a driving electric field generated by the drive electrode at a corresponding position of the detection unit in the n-th row and the (m−1)-th column is greater than a driving electric field generated by the drive electrode at a corresponding position of the detection unit in the n-th row and the m-th column, the liquid droplet moving to a corresponding position of the detection unit in the n-th row and the (m−1)-th column; and m and n being positive integers greater than or equal to 2.

Other aspects of the present disclosure can be understood by a person skilled in the art in light of the description, the claims, and the drawings of the present disclosure.

### BRIEF DESCRIPTION OF THE DRAWINGS

Accompanying drawings, which are incorporated in and constitute part of the present specification, illustrate embodiments of the present disclosure and together with a description, serve to explain principles of the present disclosure.

FIG. 1 illustrates a planar view of a microfluidic substrate consistent with various embodiments of the present disclosure;

FIG. 2 illustrates a schematic diagram of a circuit connection structure of a detection unit in FIG. 1;

FIG. 3 illustrates a planar view of a partial area of the detection unit in FIG. 1;

FIG. 4 illustrates a cross-sectional view of the detection unit in FIG. 3;

FIG. 5 illustrates another cross-sectional view of the detection unit in FIG. 3;

FIG. 6 illustrates another cross-sectional view of the detection unit in FIG. 3;

FIG. 7 illustrates another planar view of a partial area of the detection unit in FIG. 1;

FIG. 8 illustrates a cross-sectional view of the detection unit in FIG. 7;

FIG. 9 illustrates a cross-sectional view of a partial area of the microfluidic substrate in FIG. 1;

FIG. 10 illustrates another cross-sectional view of a partial area of the microfluidic substrate in FIG. 1;

FIG. 11 illustrates another cross-sectional view of the detection unit in FIG. 7;

FIG. 12 illustrates another planar view of a microfluidic substrate consistent with various embodiments of the present disclosure;

FIG. 13 illustrates an enlarged structural view of a local area in FIG. 12;

FIG. 14 illustrates another planar view of a microfluidic substrate consistent with various embodiments of the present disclosure;

FIG. 15 illustrates an enlarged structural view of a local area in FIG. 14;

FIG. 16 illustrates a planar view of a microfluidic device consistent with various embodiments of the present disclosure;

FIG. 17 illustrates a partial cross-sectional view of the microfluidic device in FIG. 16;

FIG. 18 illustrates a flow chart of a driving method of a microfluidic device consistent with various embodiments of the present disclosure;

FIG. 19 illustrates a schematic diagram of a travel and detection of a liquid droplet in FIG. 18;

FIG. 20 illustrates another schematic diagram of the travel and detection of the liquid droplet in FIG. 18;

FIG. 21 illustrates another schematic diagram of the travel and detection of the liquid droplet in FIG. 18;

FIG. 22 illustrates another schematic diagram of the travel and detection of the liquid droplet in FIG. 18; and

FIG. 23 illustrates another schematic diagram of the travel and detection of the liquid droplet in FIG. 18.

### DETAILED DESCRIPTION

Various exemplary embodiments of the present disclosure will be described in detail with reference to the accompanying drawings. It should be noted that, unless specifically stated otherwise, a relative arrangement of components and steps, numerical expressions and numerical values set forth in the embodiments do not limit the scope of the present disclosure.

The following description of at least one exemplary embodiment is merely illustrative and is not intended to limit the present disclosure and specification or use thereof.

Techniques, methods, and apparatus known to a person skilled in the art may not be discussed in detail, but where appropriate, such techniques, methods, and apparatus should be considered as part of the present specification.

In all examples shown and discussed herein, any specific value should be construed as illustrative only and is not used as a limitation. Accordingly, other examples of exemplary embodiments may have different values.

It is apparent to a person skilled in the art that various modifications and variations can be made in the present disclosure without departing from the spirit or scope of the disclosures. Accordingly, the present disclosure is intended to cover modifications and variations of the present disclosure that fall within the scope of corresponding claims (claimed technical solutions) and equivalents thereof. It should be noted that, implementations provided in the embodiments of the present disclosure may be combined with each other without conflict.

It should be noted that similar numerals and letters refer to similar items in the accompanying drawing described below. Therefore, once an item is defined in one accompanying drawing, further discussion of the item in subsequent accompanying drawings may not be required.

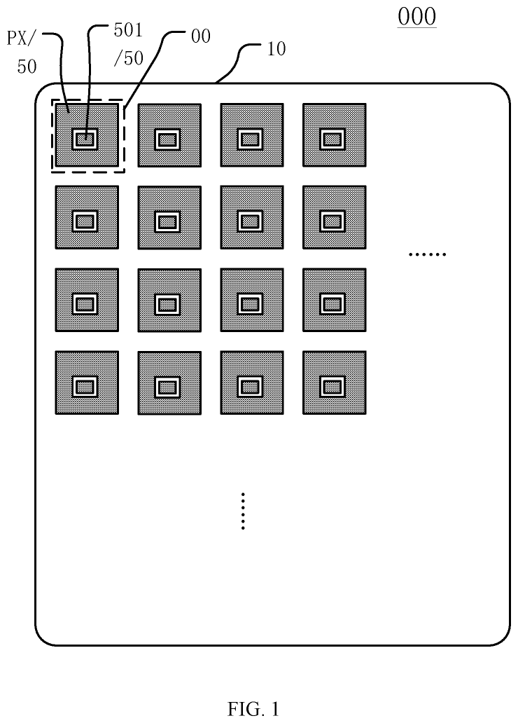

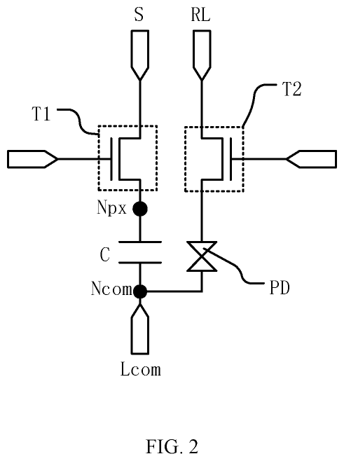

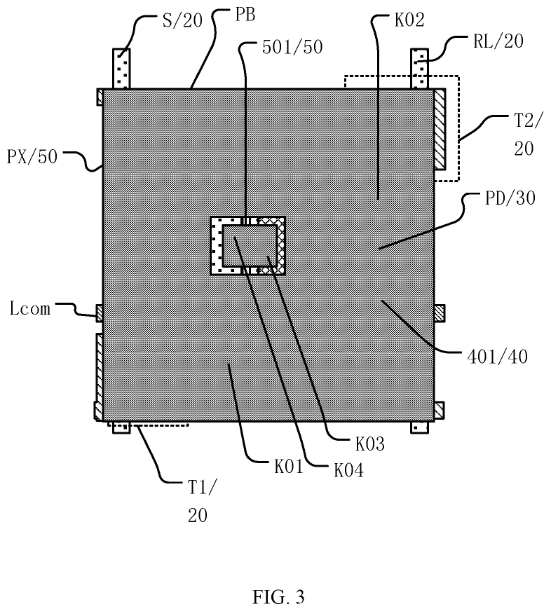

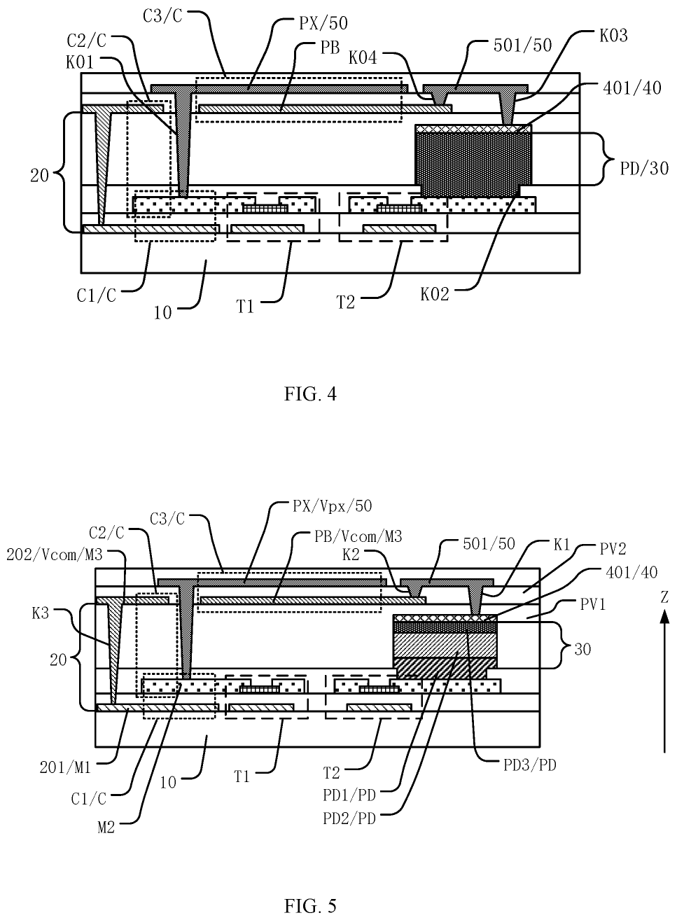

FIG. 1 illustrates a planar view of a microfluidic substrate consistent with various embodiments of the present disclosure. FIG. 2 illustrates a schematic diagram of a circuit connection structure of a detection unit in FIG. 1. FIG. 3 illustrates a planar view of a partial area of the detection unit in FIG. 1. FIG. 4 illustrates a cross-sectional view of the detection unit in FIG. 3 (it can be understood that transparency is filled in FIG. 4 to clearly illustrate a structure of one embodiment). In the embodiment, a microfluidic substrate 000 includes a plurality of detection units 00 arranged in an array. A detection unit 00 at least includes a first switch transistor T1, a second switch transistor T2, a drive electrode PX and a photosensitive element PD.

The microfluidic substrate 000 includes a base 10; a transistor array layer 20 on a side of the base 10, first switch transistors T1 and second switch transistors T2 being on the transistor array layer 20; a photosensitive element array layer 30 on a side of the transistor array layer 20 away from the base 10, photosensitive elements PD being on the photosensitive element array layer 30, and a second switch transistor T2 being electrically connected to a side of a photosensitive element PD facing the base 10; a first electrode layer 40 on a side of the photosensitive element array layer 30 away from the base 10, the first electrode layer 40 including a plurality of first electrode terminals 401, and a first electrode terminals 401 being electrically connected to a side of a photosensitive element PD away from the base 10; a second electrode layer 50 on a side of the first electrode layer 40 away from the base 10, drive electrodes PX being on the second electrode layer 50, and a first switch transistor T1 being electrically connected to a drive electrode PX; the second electrode layer 50 also including a plurality of connection parts 501, a connection part 501 being insulated from a drive electrode PX in a detection unit 00, and a first electrode terminal 401 being connected to a bias voltage part PB through the connection part 501; and a film layer where the bias voltage part PB is being on a side of the second electrode layer 50 facing the base 10.

Specifically, in the embodiment, by using the electrowetting principle, the microfluidic substrate 000 can be configured to control a flow position of a tiny liquid droplet by setting electric field intensities in different regions on the substrate, to realize driving of the tiny liquid droplet. In the embodiment, the microfluidic substrate 000 includes a plurality of detection units 00 arranged in an array. A detection unit 00 includes at least a first switch transistor T1, a second switch transistor T2, a drive electrode PX and a photosensitive element PD that are electrically connected. The drive electrode PX can be configured to provide a voltage/electric field to drive the tiny liquid droplet, and the photosensitive element PD can be configured to optically detect the tiny liquid droplet to analyze a fluorescence intensity and corresponding droplet components. Or the photosensitive element PD can also be configured to feed back a position of the liquid droplet in real time through an optical detection of the photosensitive element PD during a movement of the liquid droplet, to precisely control a path of the liquid droplet. In the embodiment, the first switch transistor T1 can be connected to the drive electrode PX, and a first electrode of the first switch transistor T1 can be connected to a data line S on the microfluidic substrate 000. A data voltage signal is provided to the first electrode of the first switch transistor T1 through the data line S. A second electrode of the first switch transistor T1 can be connected to the drive electrode PX (i.e., the drive electrode PX can be connected to Npx in FIG. 2). The first switch transistor T1 serves as a switching element that provides a voltage signal to the drive electrode PX. When the first switch transistor T1 is turned on, the data line S can apply a data voltage signal to the drive electrode PX, to provide a voltage/electric field for driving the liquid droplet to travel. In the embodiment, the second switch transistor T2 can be connected to the photosensitive element PD, a first electrode of the second switch transistor T2 can be connected to a photosensitive signal detection terminal RL, and a second electrode of the second switch transistor T2 can be connected to the photosensitive element PD. The second switch transistor T2 serves as a switching element for outputting a photodetection signal from the photosensitive element PD. When the second switch transistor T2 is turned on, the photodetection signal sensed by the photosensitive element PD can be output through the photosensitive signal detection terminal RL.

It can be understood that, in the embodiment, both the first switch transistor T1 and the second switch transistor T2 in FIG. 2 are taken as P-type transistors as an example for illustration. During specific implementation, the first switch transistor T1 and the second switch transistor T2 may both be N-type transistors, or one of the first switch transistor T1 and the second switch transistor T2 is a P-type transistor, and the other of the first switch transistor T1 and the second switch transistor T2 is an N-type transistor, which is not limited herein.

In the embodiment, the microfluidic substrate 000 includes the base 10, which can be configured as a carrier substrate for forming other structures of the microfluidic substrate 000 thereon. The transistor array layer 20 is on a side of the base 10. Optionally, the transistor array layer 20 may include a plurality of conductive metal layers and a plurality of insulating layers, which is not described in detail herein. The first switch transistor T1 and the second switch transistor T2 of each detection unit 00 may be on the transistor array layer 20. Optionally, the plurality of conductive metal layers included on the transistor array layer 20 can also be configured to form various signal lines on the substrate, such as data lines S or detection signal lines for outputting photosensitive detection signals or scanning signal lines for controlling turning-on and turning-off of the first switch transistor T1 and the second switch transistor T2, which are not limited herein. The photosensitive element array layer 30 is on a side of the transistor array layer 20 away from the base 10, and the photosensitive element PD may be on the photosensitive element array layer 30. Optionally, in the embodiment, the photosensitive element PD in figures is taken as a PIN photodiode as an example for illustration. During specific implementation, the photosensitive element PD can be specifically set as a photodiode or another photosensitive element according to a photosensitive detection requirement, which is not limited herein. In the embodiment, the second switch transistor T2 may be electrically connected to a side of the photosensitive element PD facing the base 10, so that the second switch transistor T2 serves as a switching element for the photosensitive element PD to output a photodetection signal. Optionally, the second electrode of the second switch transistor T2 may be connected to the photosensitive element PD through at least one via hole (marked with K insulating layer). When the second switch transistor T2 is turned on, a photodetection signal (e.g., a photogenerated current signal) sensed by the photosensor PD can be output through the photosensitive signal detection terminal RL. In the embodiment, the first electrode layer 40 is on a side of the photosensitive element array layer 30 away from the base 10. The first electrode layer 40 can be configured at least to form a plurality of first electrode terminals 401. The first electrode terminal 401 is electrically connected to a side of the photosensitive element PD away from the base 10. Optionally, as shown in FIG. 4, the first electrode terminal 401 may directly cover the side of the photosensitive element PD away from the base 10, and directly contact the side of the photosensitive element PD away from the base 10 to realize an electrical connection. The second electrode layer 50 is on the side of the first electrode layer 40 away from the base 10. The second electrode layer 50 is configured to form the drive electrode PX of the detection unit 00. The first electrode (or drain) of the first switch transistor T1 may be electrically connected to the drive electrode PX, so that the first switch transistor T1 serves as a switching element providing a voltage signal to the drive electrode PX. Optionally, the first electrode of the first switch transistor T1 can be connected to the photosensitive element PD through at least one via hole (marked with K01), so that the data line S can apply a data voltage signal to the drive electrode PX to form an electric field to drive the liquid droplet to travel when the first switch transistor T1 is turned on.

In one embodiment, the second electrode layer 50 further includes a plurality of connection parts 501. Optionally, one connection part 501 may correspond to one detection unit 00, the connection parts 501 and the drive electrode PX in one detection unit 00 are insulated from each other, that is, although the connection part 501 and the drive electrode PX are both on the second electrode layer 50. However, the connection part 501 and the drive electrode PX in a same detection unit 00 are mutually independent structures. It can be understood that, in the embodiment, a size of a space occupied by the connection part 501 and the drive electrode PX in the area where a detection unit 00 is located is not specifically limited, and only needs to meet a size of the drive electrode PX to drive the liquid droplet to travel.

In the embodiment, the first electrode terminal 401 covering the side of the photosensitive element PD away from the base 10 is connected to the bias voltage part PB through the connection part 501 of the second electrode layer 50. Optionally, the connection part 501 may be connected to the first electrode terminal 401 through at least one via hole (marked with K03), and the connection part 501 may be connected to the bias voltage part PB through at least one via hole (marked with K04). The bias voltage part PB can be connected with a common voltage signal, so that the common voltage signal on the bias voltage part PB is transmitted to the photosensitive element PD through the first electrode terminal 401, and the common voltage signal can be multiplexed as a bias voltage signal of the photosensitive element PD. When the photosensitive element PD is a PIN photodiode, the PIN photodiode needs to apply the bias voltage signal to perform a photosensitive detection. The bias voltage signal can be multiplexed with a common voltage signal and input through the bias voltage part PB, so that the photosensitive element PD in the detection unit 00 can perform a photosensitive detection. Since the bias voltage part PB is connected to a constant common voltage signal, the bias voltage part PB can also form a storage capacitor C with a drive electrode PX. When the first switch transistor T1 is turned on, the drive electrode PX is connected to the data voltage signal, the storage capacitor C shown in FIG. 2 can be configured to maintain an electric field driving the liquid droplet to ensure a liquid droplet's traveling effect.

It can be understood that, in the embodiment, a film layer where the bias voltage part PB is located is not specifically limited, and only needs to be on a side of the second electrode layer 50 facing the base 10 and does not occupy a space of the second electrode layer 50 where the drive electrode PX is located.

In one embodiment, by setting the connection part 501 on a same layer as the drive electrode PX but independent of each other on the second electrode layer 50 where the drive electrode PX is located, a common voltage signal provided on the bias voltage part PB connected to the connection part 501 is configured as a bias voltage signal of the photosensitive element PD, and is transmitted to the first electrode terminal 401 on the side of the photosensitive element PD away from the base 10, so that the photosensitive element PD receives the bias voltage signal during sensing to realize a photosensitive function thereof. Since the bias voltage part PB is electrically connected to the photosensitive element PD through the connection part 501 of the same layer as the drive electrode PX, the bias voltage part PB can not only provide a bias voltage signal for the photosensitive element PD through the connection part 501, but also can be configured to overlap the drive electrode PX to form the storage capacitor C to drive the liquid droplet to travel, thereby reducing an area occupied by signal wires and capacitors in a single detection unit 00, and increasing a photoelectric detection area of the photosensitive element PD in the single detection unit 000, which is conductive to ensuring a sensing effect of the photosensitive element PD, improving an efficiency and accuracy of optical detection, and realizing a high-density and high-precision photoelectric detection.

In the art, in a structure in which a bias voltage part providing a bias voltage signal is separated from a common electrode part providing a common voltage signal, a storage capacitor is mainly formed by an overlapping structure of a film layer where a gate of a switch transistor is located and a film layer where a source and drain of the switch transistor. When a large enough storage capacitor value is required to ensure an effect of driving a liquid droplet to travel, a space required for a storage capacitor in a single detection unit is relatively large, and a bias voltage part that provides a bias voltage signal also needs to occupy a certain space in the single detection unit. Therefore, a setting area left for the photosensitive element in the single detection unit is limited, which easily leads to a limited detection signal strength of the photosensitive element, thereby making the photosensitive element difficult to achieve both high-precision photosensitive detection and microfluidic drive.

To solve the above problems, in one embodiment, the bias voltage part PB connected with a common voltage signal is not only configured to provide a bias voltage signal for the photosensitive element PD, but also configured to form a storage capacitor with the drive electrode PX. Under a condition that a capacitance value required to drive a liquid droplet to travel remains unchanged, a storage capacitor occupies a smaller area of the detection unit 00. As shown in FIG. 4, the storage capacitor C in the single detection unit 00 may include a first storage capacitor C1 formed by an overlapping structure of a film layer (a structure connected to the common voltage signal) where a gate of the first switch transistor T1 is located and a film layer where the first electrode of the first switch transistor T1 is located (the first electrode of the first switch transistor T1 is connected to the drive electrode PX, which is equivalent to connecting the first electrode of the first switch transistor T1 and the drive electrode PX to a same signal). A second storage capacitor C2 may also be formed by using an overlapping structure of a film layer where the first electrode of the first switch transistor T1 is located (the first electrode of the first switch transistor T1 is connected to the drive electrode PX, which is equivalent to connecting the first electrode of the first switch transistor T1 and the drive electrode PX to a same signal) and the bias voltage part PB structure. A third storage capacitor C3 may also be formed by using an overlapping structure of the bias voltage part PB and the drive electrode PX. That is, the storage capacitor C in the single detection unit 00 may be formed by at least the first storage capacitor C1, the second storage capacitor C2, and the third storage capacitor C3. When a capacitance value required by the detection unit 00 remains unchanged, an area occupied by a storage capacitor can be reduced, which is conductive to increasing an available area of the photosensitive element PD in the detection unit 00. An intensity of a detectable photosensitive detection signal can be increased, thereby improving an efficiency and accuracy of optical detection, and realizing a high-density and high-precision photoelectric detection.

It should be noted that, in the embodiment, figures only schematically show a structure of the microfluidic substrate 000. During specific implementation, the structure of the microfluidic substrate includes, but is not limited to the structure, and may include other structures that enable droplet travel and photoelectric detection, such as hydrophobic layers on the microfluidic substrate. For details, reference may be made to microfluidic substrates in a related microfluidic technology, which is not be described in detail herein.

It can be understood that, to clearly illustrate a film layer structure of the detection unit 00 in the embodiment, only part of the film layers on the base 10 are shown in FIG. 3. Other related film layers such as a semiconductor layer serving as the active part of the transistor are not shown. During specific implementation, references can be made to a film layer structure of a thin film transistor in a related art for understanding.

In some optional embodiments, referring to FIGS. 1-3, FIG. 5 illustrates another cross-sectional view of the detection unit in FIG. 3. In one embodiment, the photosensitive element PD includes an N-type semiconductor portion PD1, an intrinsic semiconductor portion PD2, and a P-type semiconductor portion PD3 that arranged in a stack. The intrinsic semiconductor portion PD2 is between the N-type semiconductor portion PD1 and the P-type semiconductor portion PD3. The N-type semiconductor portion PD1 is connected to a drain of the second switch transistor T2. The P-type semiconductor portion PD3 is electrically connected to the first electrode terminal 401. The connection part 501 is connected to the first electrode terminal 401 through the first via hole K1. The connection part 501 is connected to the bias voltage part PB through the second via hole K2. The first via hole K1 and the second via hole K2 are formed in same steps and in a same process.

The embodiment explains that the photosensitive element PD configured for photosensitive detection in the microfluidic substrate 000 can be a PIN-type photodiode. The photosensitive element PD includes the N-type semiconductor portion PD1, the intrinsic semiconductor portion PD2, and the P-type semiconductor portion PD3 that are arranged in a stack. The intrinsic semiconductor portion PD2 is between the N-type semiconductor portion PD1 and the P-type semiconductor portion PD3. A layer of the intrinsic semiconductor portion PD2 is sandwiched between the N-type semiconductor portion PD1 and the P-type semiconductor portion PD3. When the photosensitive element PD of the structure performs photosensitive detection, most of the incident light is absorbed in the intrinsic semiconductor portion PD2 and generates many electron-hole pairs, thereby realizing photosensitive detection is by absorbing light radiation to generate photocurrent. A PIN photodiode has advantages of small junction capacitance, fast response speed, high sensitivity and the like, which can improve a photosensitive detection capability of the photosensitive element PD in the detection unit 00. In the embodiment, the drain of the second switch transistor T2 serving as the switching element of the photosensitive element PD is connected to the N-type semiconductor part PD1 of the photosensitive element PD, and is configured for direct electric connection between the first electrode terminal 401 connected to the bias voltage part PB that provides a bias voltage signal and the P-type semiconductor part PD3 of the photosensitive element PD. That is, the first electrode terminal 401 can directly cover a side of the P-type semiconductor portion PD3 away from the base 10, which is conductive to reducing number of insulating layers and via holes on the substrate and reduce process steps.

In one embodiment, after a structure of the first electrode end 401 of the first electrode layer 40 is formed, a first insulating layer PV1 (not filled in FIG. 5) can be arranged on the microfluidic substrate 000 to cover a structure of the first electrode end 401 to insulate and protect the first electrode terminal 401. A structure of the bias voltage part PB is formed on a side of the first insulating layer PV1 far away from the base 10, and the bias voltage part PB is covered by the second insulating layer PV2 (not filled in FIG. 5), to insulate and protect the bias voltage part PB. The first via hole K1 and the second via hole K2 with different depths can be formed by photolithography at different positions of the second insulating layer PV2 through a mask plate, so that after the second electrode layer 50 is formed on the second insulating layer PV2 away from the base 10, the connection part 501 of the second electrode layer 50 is connected to the first electrode terminal 401 through the deeper first via hole K1 (the first via hole K1 penetrates at least the second insulating layer PV2 and at least part of the first insulating layer PV1). The connection part 501 is connected to the bias voltage part PB through the shallower second via hole K2 (the second via hole K2 penetrates at least the second insulating layer PV2). That is, in the embodiment, although the connection part 501 and the drive electrode PX are both arranged on the second electrode layer 50, the connection part 501 and the drive electrode PX in a same detection unit 00 are mutually independent structures, so that the connection part 501 can be connected to the first electrode terminal 401 through the first via hole K1. When the connection part 501 is connected to the bias voltage part PB through the second via hole K2, the first via hole K1 and the second via hole K2 can apply a photolithography process of deep and shallow holes to complete etching of two via holes at different positions in a same process step through a same mask plate, which can reduce a mask plate in a whole process and reduce a process cost.

Some optional embodiments can be referred to FIGS. 1-4. In one embodiment, the bias voltage part PB is connected to a bias voltage signal line Lcom, the bias voltage part PB and the bias voltage signal line Lcom are arranged on a same layer, and the bias voltage signal line Lcom is connected to a common voltage signal.

The embodiment explains that, in the microfluidic substrate 000, the bias voltage signal line Lcom can be arranged on a same layer as the bias voltage part PB. The bias voltage signal line Lcom is connected to a common voltage signal, so that the bias voltage part PB can be connected to the common voltage signal and connected to the photosensitive element PD through the connection part 501 and used as the photosensitive element PD to provide a bias voltage signal. In the embodiment, the bias voltage part PB and the bias voltage signal line Lcom are arranged on a same layer, so the bias voltage signal line connected to the common voltage signal can overlap the drive electrode PX to form a storage capacitor, which can further increase an area of a film layer where the bias voltage part PB overlaps the drive electrode PX. When a required capacitance value of the detection unit 00 remains unchanged, an overall area of the storage capacitor occupied by the detection unit 00 can be reduced, which is conductive to increasing a usable area of the photosensitive element PD in the detection unit 00 and improving an efficiency and accuracy of optical detection.

It can be understood that, in some other optional embodiments, the bias voltage signal line Lcom can also be arranged on a different layer from the bias voltage part PB. For example, the bias voltage signal line Lcom can be arranged on a same layer as the gate of the first switch transistor T1, and can be electrically connected to the bias voltage part PB through a via hole, to provide a common voltage signal for the bias voltage part PB, which is not limited herein.

Referring to FIGS. 1-3 and FIG. 5, in one embodiment, the detection unit 00 includes the storage capacitor C. A first electrode of the storage capacitor C is connected to the bias voltage part PB at a node Ncom in FIG. 2, i.e., the first electrode of the storage capacitor C is connected to a common voltage signal Vcom provided by the bias voltage part PB. A second electrode of the storage capacitor C is connected to the drive electrode PX at a node Npx in FIG. 2, i.e., the second electrode of the storage capacitor C is connected to a data voltage signal Vpx provided by the data line S to the drive electrode PX. Furthermore, while a driving voltage/electric field for driving a liquid droplet to travel can be formed at the drive electrode PX of each detection unit 00, an intensity of the driving electric field can also be maintained through the storage capacitor C, to ensure a normal travel of the liquid droplet on the microfluidic substrate 000.

Optionally, referring to FIGS. 1-3 and FIG. 5, in one embodiment, the storage capacitor C of the detection unit 00 includes at least a first storage capacitor C1. The transistor array layer 20 includes at least a first metal layer M1 and a second metal layer M2, the first metal layer M1 includes a plurality of first parts 201, and a drain of the first switch transistor T1 is on the second metal layer M2. The bias voltage part PB is on the third metal layer M3, and the third metal layer M3 is on a side of the transistor array layer 20 away from the second metal layer M2. In a direction Z perpendicular to a plane where the base 10 is located, a first part 201 overlaps the drain of the first switch transistor T1 to form the first storage capacitor C1.

The embodiment explains that, while the detection unit 00 on the microfluidic substrate 000 is arranged with the storage capacitor C to maintain an electric field intensity driving a liquid droplet through the storage capacitor C to ensure a normal travel of the liquid droplet on the microfluidic substrate 000, a structure connected to an electric signal of the drive electrode PX can overlap a structure connected to a common voltage signal to form the storage capacitor C in a film layer structure on the base 10. Specifically, the transistor array layer 20 includes at least the first metal layer M1 and the second metal layer M2. The first metal layer M1 can be configured to form gates of the first switch transistor T1 and the second switch transistor T2. The second metal layer M2 can be configured to form a source and drain of the first switch transistor T1. The second metal layer M2 can also be configured to form a source and drain of the second switch transistor T2. The second metal layer M2 can also be configured to form the data line S and the like, which is described in detail herein. The bias voltage part PB connected to a common voltage signal may be on the third metal layer M3, and the third metal layer M3 is on a side of the transistor array layer 20 away from the second metal layer M2, that is, the third metal layer M3 may be arranged on a side of the second metal layer M2 facing a film layer where the drive electrode PX is located. In one embodiment, the first metal layer M1 is arranged to include a plurality of first parts 201. Optionally, a first part 201 of the first metal layer M1 may be electrically connected to the bias voltage part PB of the third metal layer M3 through a via hole, so that the first part 201 is connected to a common voltage signal. The drain of the first switch transistor T1 is electrically connected to the drive electrode PX, so the drain of the first switch transistor T1 can be understood as a potential signal connected to of the drive electrode PX. In one embodiment, in the direction Z perpendicular to the plane where the base 10 is located, the first part 201 can overlap the drain of the first switch transistor T1 to form the first storage capacitor C1, so that a first electrode of the first storage capacitor C1 is connected to a common voltage signal provided by the bias voltage part PB. A second electrode of the first storage capacitor C1 is connected to a data voltage signal provided by the data line S to the drive electrode PX. The electric field intensity driving the liquid droplet to travel is maintained by the first storage capacitor C1 to ensure a normal travel of the liquid droplet on the microfluidic substrate 000.

Optionally, referring to FIGS. 1-3 and FIG. 5, in one embodiment, the storage capacitor C also includes the second storage capacitor C2. The third metal layer M3 includes second parts 202, and a second part 202 is connected to a first part 201 through the third via hole K3. In the direction Z perpendicular to the plane of the base 10, the second part 202 overlaps the drain of the first switch transistor T1 to form the second storage capacitor C2.

The embodiment explains that, while the detection unit 00 on the microfluidic substrate 000 is arranged with the storage capacitor C to maintain an electric field intensity driving a liquid droplet through the storage capacitor C to ensure a normal travel of the liquid droplet on the microfluidic substrate 000, a structure connected to an electric signal of the drive electrode PX can overlap a structure connected to a common voltage signal to form a film layer structure of the storage capacitor C on the base 10. Specifically, in the direction Z perpendicular to the plane where the base 10 is located, the first part 201 can overlap the drain of the first switch transistor T1 to form the first storage capacitor C1. The storage capacitor C may include a structure in which the second part 202 overlaps the drain of the first switch transistor T1. The second part 202 is on the third metal layer M3. The second part 202 is connected to the first part 201 through the third via hole K3, so that the second part 202 is connected to a common voltage signal. The drain of the first switch transistor T1 is electrically connected to the drive electrode PX, so the drain of the first switch transistor T1 can be understood as a potential signal connected to the drive electrode PX. In the direction Z perpendicular to the plane where the base 10 is located, the second part 202 overlaps the drain of the first switch transistor T1 to form the second storage capacitor C2, so that a first electrode of the second storage capacitor C2 is connected to a common voltage signal provided by the bias voltage part PB. A second electrode of the second storage capacitor C2 is connected to a data voltage signal provided by the data line S to the drive electrode PX. While the first storage capacitor C1 and the second storage capacitor C2 are used together as the storage capacitor C to maintain an electric field intensity driving a liquid droplet to travel to ensure a normal travel of the liquid droplet on the microfluidic substrate 000, under a condition that a required capacitance value of the detection unit 00 remains unchanged, an area of the detection unit 00 occupied by the storage capacitor is reduced, which is conductive to increasing an available area of the photosensitive element PD in the detection unit 00.

Optionally, referring to FIGS. 1-3 and FIG. 5, in one embodiment, the storage capacitor C also includes a third storage capacitor C3. In the direction Z perpendicular to the plane where the base 10 is located, the bias voltage part PB overlaps the drive electrode PX to form the third storage capacitor C3.

The embodiment explains that, while the detection unit 00 on the microfluidic substrate 000 is arranged with the storage capacitor C to maintain an electric field intensity driving a liquid droplet to travel to ensure a normal travel of the liquid droplet on the microfluidic substrate 000, a structure connected to an electric signal of the drive electrode PX can overlap a structure connected to a common voltage signal to form a film layer structure of the storage capacitor C on the base 10. Specifically, in a direction Z perpendicular to the plane of the base 10, the first part 201 of the first metal layer M1 can overlap the drain of the first switch transistor T1 to form the first storage capacitor C1. In a direction Z perpendicular to the plane of the base 10, the second part 202 of the third metal layer M3 can overlap the drain of the first switch transistor T1 to form the second storage capacitor C2. The storage capacitor C may include a structure formed by overlapping the bias voltage part PB and the drive electrode PX. The bias voltage part PB is connected to a common voltage signal. The drive electrode PX is connected to a potential signal provided by the data line S. In the direction Z perpendicular to the plane where the base 10 is located, the bias voltage part PB overlaps the drive electrode PX to form a third storage capacitor C3, so that a first electrode of the third storage capacitor C3 is connected to a common voltage signal provided by the bias voltage part PB. A second electrode of the third storage capacitor C3 is connected to a data voltage signal provided by the data line S to the drive electrode PX. While the first storage capacitor C1, the second storage capacitor C2 and the third storage capacitor C3 are used together as storage capacitors C to maintain an electric field intensity driving a liquid droplet to travel to ensure a normal travel of the liquid droplet on the microfluidic substrate 000, an area of the detection unit 00 occupied by the storage capacitor as a whole can be further reduced under a condition that the required capacitance value of the detection unit 00 remains unchanged, which is conductive to further increasing a usable area of the photosensitive element PD in the detection unit 00.

Optionally, referring to FIGS. 1-3, FIG. 6 illustrates another cross-sectional view of the detection unit in FIG. 3. In one embodiment, the storage capacitor C also includes a fourth storage capacitor C4. In the direction Z perpendicular to the plane where the base 10 is located, the first electrode terminal 401 overlaps the drive electrode PX to form the fourth storage capacitor C4.

The embodiment explains that, while the detection unit 00 on the microfluidic substrate 000 is arranged with the storage capacitor C to maintain an electric field intensity driving a liquid droplet through the storage capacitor C to ensure a normal travel of the liquid droplet on the microfluidic substrate 000, a structure connected to the electric signal of the drive electrode PX can overlap a structure connected to the common voltage signal to form the storage capacitor C in a film layer structure on the base 10. Specifically, in a direction Z perpendicular to the plane of the base 10, the first part 201 of the first metal layer M1 can overlap the drain of the first switch transistor T1 to form the first storage capacitor C1. In a direction Z perpendicular to the plane of the base 10, the second part 202 of the third metal layer M3 can overlap the drain of the first switch transistor T1 to form the second storage capacitor C2. In the direction Z perpendicular to the plane of the base 10, the bias voltage part PB can overlap and the drive electrode PX to form the third storage capacitor C3. The storage capacitor C may include a structure in which the first electrode terminal 401 overlaps the drive electrode PX. The first electrode terminal 401 is connected to the bias voltage part PB connected to a common voltage signal through the connection part 501, that is, a signal of the first electrode terminal 401 is a common voltage signal. The drive electrode PX is connected to a potential signal provided by the data line S. In the direction Z perpendicular to the plane where the base 10 is located, the first electrode terminal 401 of the first electrode layer 40 overlaps the drive electrode PX of the second electrode layer 50 to form the fourth storage capacitor C4, so that a first electrode of the fourth storage capacitor C4 is connected to a common voltage signal provided by the bias voltage part PB. The second electrode of the fourth storage capacitor C4 is connected to the data voltage signal provided by the data line S to the drive electrode PX. While the first storage capacitor C1, the second storage capacitor C2, the third storage capacitor C3 and the fourth storage capacitor C4 are used together as the storage capacitor C to maintain an electric field intensity driving a liquid droplet to travel to ensure a normal travel of the liquid droplet on the microfluidic substrate 000, an area of the detection unit 00 occupied by the storage capacitor can be further reduced under a condition that a required capacitance value of the detection unit 00 remains unchanged, which is conductive to increasing a usable area of the photosensitive element PD in the detection unit 00, so that an area of the photosensitive element PD in the detection unit 00 is large enough, an intensity of a detectable photosensitive detection signal can be further improved, which is conducive to further improving an efficiency and accuracy of optical detection and realizing a high-density and high-precision photoelectric detection.

Referring to FIGS. 1-3 and FIG. 6, in one embodiment, the third metal layer M3 is located between the first electrode layer 40 and the second electrode layer 50.

The embodiment explains that, when a film layer where the bias voltage part PB is located, i.e., the third metal layer M3 is arranged on a side of the second electrode layer 50 facing the base 10, the third metal layer M3 can be arranged between the first electrode layer 40 and the second electrode layer 50. That is, the third metal layer M3 is at least on a side of the photosensitive element array layer 30 away from the base 10, so that when the connection part 501 is connected to the bias voltage part PB of the third metal layer M3 through the second via hole K2, a depth of the second via hole K2 penetrating through the second insulating layer PV2 is relatively shallow, which is conductive to ensuring a process yield of the second via hole K2, and further improving a stability of the electrical connection between the connection part 501 of the second electrode layer 50 and the bias voltage portion PB of the third metal layer M3.

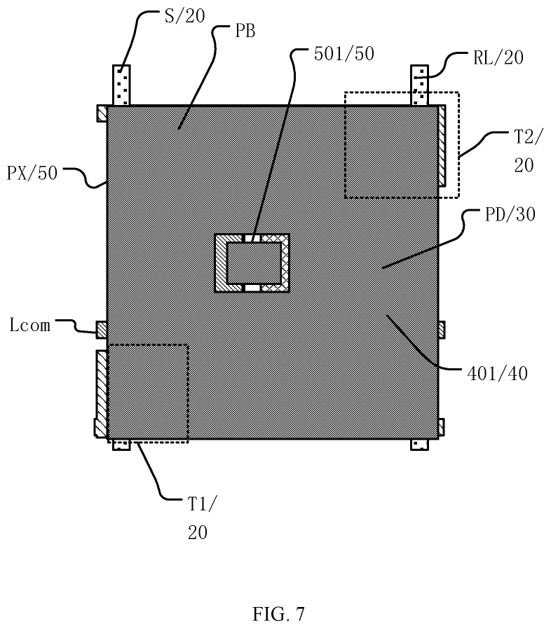

In some optional embodiments, referring to FIG. 1, FIG. 7 illustrates another planar view of a partial area of the detection unit in FIG. 1, and FIG. 8 illustrates a cross-sectional view of the detection unit in FIG. 7 (it can be understood that transparency is filled in FIG. 8 to clearly illustrate a structure in one embodiment). In the embodiment, the third metal layer M3 is between the photosensitive element array layer 30 and the transistor array layer 20.

The embodiment explains that, when a film layer where the bias voltage part PB is located, that is, the third metal layer M3 is arranged on a side of the second electrode layer 50 facing the base 10, the third metal layer M3 can be arranged on the photosensitive element array layer 30 and the transistor array layer 20. Optionally, the third metal layer M3 may be located on a side of the second metal layer M2 away from the base 10. After a source and drain of the transistor of the second metal layer M2 and a signal wiring are formed, a planarization layer 01 can be arranged to cover a patterned structure of the second metal layer M2 to achieve a flat effect. The third metal layer M3 can be arranged above the planarization layer 01, so that after the first electrode layer 40 above the photosensitive element array layer 30 is formed, the third metal layer M3 can be directly covered by the first insulating layer PV1, and a structure of the second electrode layer 50 can be formed above the first insulating layer PV1. Compared with a structure including two insulating layers between the second electrode layer 50 and the first electrode layer 40 in the above embodiment, the embodiment can reduce number of layers of the insulating layer, which is conductive to further reducing a manufacturing cost and improve a process efficiency. Since only the first insulating layer PV1 is between the second electrode layer 50 and the first electrode layer 40, a distance between the second electrode layer 50 and the first electrode layer 40 can be reduced, which is conductive to increasing a value of the storage capacitor formed, i.e., the fourth storage capacitor C4 by overlapping the first electrode terminal 401 and the drive electrode PX within a unit area. The calculation formula of capacitance C is C=εS/d, ε is a dielectric constant of a medium between plates, S is an overlapping area of the plates, and d is a spacing between the plates, which is equivalent to that, in the embodiment, the smaller a spacing between the second electrode layer 50 and the first electrode layer 40, the larger a capacitance value. When the capacitance value required by the detection unit 00 remains unchanged, an overall area of the detection unit 00 occupied by the storage capacitor C can be further reduced, and a setting area of the photosensitive element PD in the detection unit 00 can be large enough to further improve an efficiency and accuracy of optical detection.

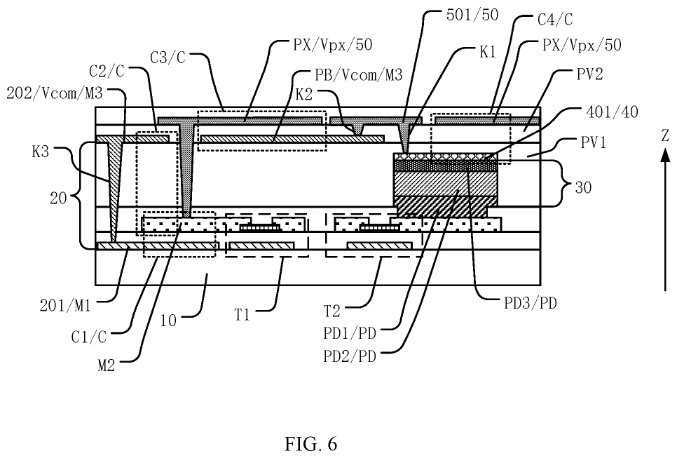

It can be understood that although the film layer where the bias voltage part PB is located shown in FIG. 8 is different from the film layer where the bias voltage portion PB is located in the embodiment of FIGS. 5 and 6, the storage capacitor C formed in the detection unit 00 can be same. That is, as shown in FIG. 8, the detection unit 00 in the embodiment includes the storage capacitor C composed of the first storage capacitor C1, the second storage capacitor C2, the third storage capacitor C3 and the fourth storage capacitor C4 to ensure that, while the first storage capacitor C1, the second storage capacitor C2, the third storage capacitor C3 and the fourth storage capacitor C4 are used together as the storage capacitor C to maintain the electric field intensity for driving the liquid droplet to travel, an area occupied by the storage capacitor as a whole of the detection unit 00 is further reduced under a condition that a required capacitance value of the detection unit 00 remains unchanged.

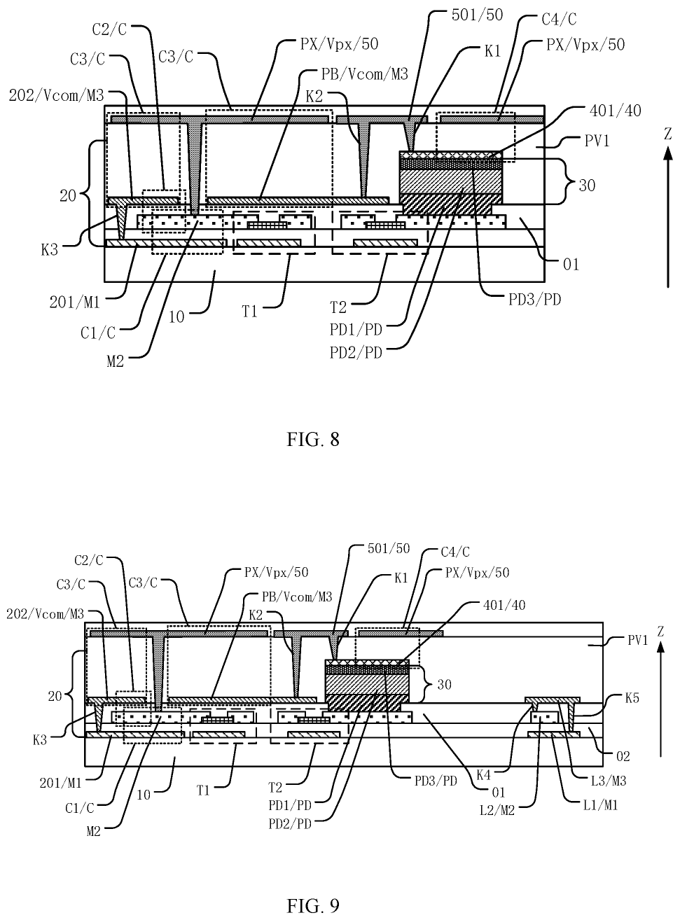

Some optional embodiments can be referred to FIG. 1, FIG. 7 and FIG. 9. FIG. 9 illustrates a cross-sectional view of a partial area of the microfluidic substrate in FIG. 1. In one embodiment, the first metal layer M1 includes a first signal line L1, the second metal layer M2 includes a second signal line L2, and the third metal layer M3 includes a third signal line L3. The third signal line L3 is connected to the second signal line L2 through a fourth via hole K4, and the third signal line L3 is connected to the first signal line L1 through a fifth via hole K5. The fourth via hole K4 and the fifth via hole K5 are formed in same steps and in a same process.

The embodiment explains that the base 10 in the microfluidic substrate 000 may include a plurality of signal lines on different film layers. For example, the first metal layer M1 includes the first signal line L1, the second metal layer M2 includes the second signal line L2, and the third metal layer M3 includes the third signal line L3. When the signal lines located on different metal film layers need to be electrically connected so that the signals transmitted on the signal lines are consistent, that is, the first signal line L1 of the first metal layer M1 and the second signal line L3 of the third metal layer M3 need to be electrically connected to each other, a wire-switching connection may be performed through the second signal line L2 of the second metal layer M2. In the art, when different layers are connected, generally, an insulating layer above the first signal line is used to punch a via hole, and the second signal line is connected to the first signal line through the via hole. An insulating layer above the second signal line is used to punch a via hole again, and the third signal line is connected to the second signal line through the via hole, thereby realizing a mutual electrical connection between the first signal line of the first metal layer and the third signal line of the third metal layer. In the above structure, at least two insulating layers need to be punched separately, two masks are required, and the above structure can be formed through two photolithography exposure processes, which requires many steps and high cost. In the embodiment, the third signal line L3 is connected to the second signal line L2 through the fourth via hole K4, the third signal line L3 is connected to the first signal line L1 through the fifth via hole K5, and the fourth via hole K4 and the fifth via hole K5 are formed in same steps and in a same process. That is, after the first signal line L1 of the first metal layer M1 is formed, a third insulating layer 02 is covered. The third insulating layer 02 at a position of the first signal line L1 does not need to be punched, after the second metal layer M2 is directly formed and a pattern of the second signal line L2 is formed, a planarization layer 01 is formed on the second metal layer M2 to cover the second metal layer M2. Etching of the fourth via hole K4 and the fifth via hole K5 at two different positions can be completed in a same process step directly through a mask plate using a photolithography process of deep and shallow holes, so that the fourth via hole K4 is relatively shallow, and the fifth via hole K5 is relatively deep. The third signal line L3 of the third metal layer M3 is connected to the second signal line L2 of the second metal layer M2 through the shallower fourth via hole K4 (the fourth via hole K4 at least penetrates the planarization layer 01). The third signal line L3 of the third metal layer M3 is connected to the first signal line L1 of the first metal layer M1 through the fifth deeper via hole K5 (the fifth via hole K5 at least penetrates the planarization layer 01 and the third insulating layer 02), which can reduce a mask plate in a whole process, and is conducive to reducing a process cost.

It can be understood that, in the embodiment, setting positions and connected signals of the first signal line L1 of the first metal layer M1, the second signal line L2 of the second metal layer M2, and the third signal line L3 of the third metal layer M3 are not specifically limited herein. The first signal line L1 of the first metal layer M1, the second signal line L2 of the second metal layer M2, and the third signal line L3 of the third metal layer M3 may in the detection unit 00 of the microfluidic substrate 000 to realize a wire-changing connection of wiring on different layers of the detection unit 00. Or the first signal line L1 of the first metal layer M1, the second signal line L2 of the second metal layer M2, and the third signal line L3 of the third metal layer M3 may also be in a frame area of the microfluidic substrate 000 to realize a wire-changing connection of peripheral wiring. In FIG. 9, the signal lines are shown together with a cross-sectional view of the detection unit 00 only for a purpose of using positions of different metal film layers as a reference. During specific implementation, setting positions and connected signals of the first signal line L1 of the first metal layer M1, the second signal line L2 of the second metal layer M2, and the third signal line L3 of the third metal layer M3 can be designed according to actual needs, which are not limited herein.

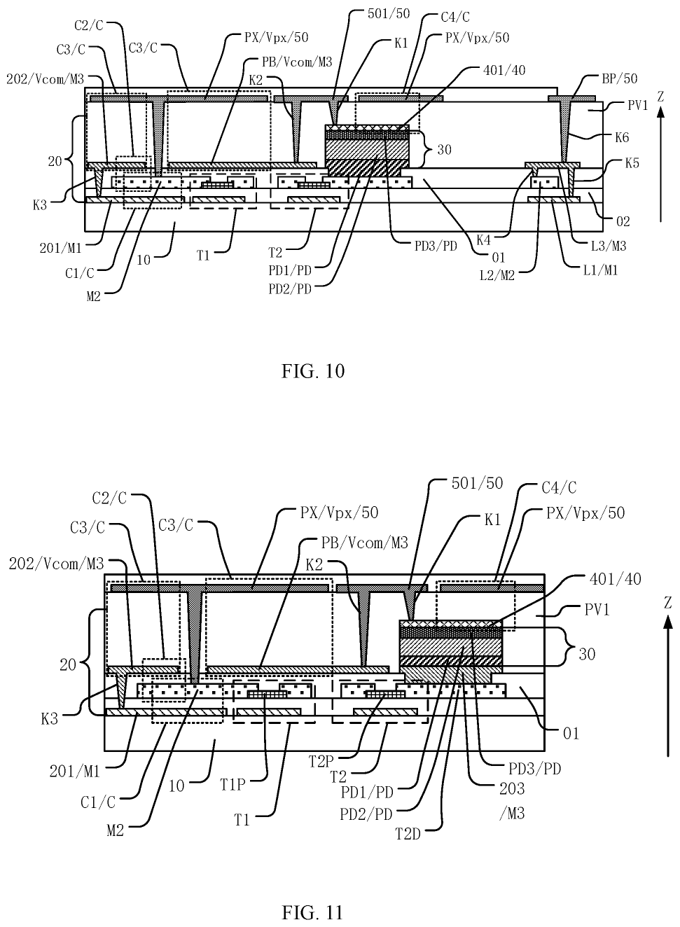

In some optional embodiments, referring to FIG. 1 and FIG. 7, FIG. 10 illustrates another cross-sectional view of a partial area of the microfluidic substrate in FIG. 1. In one embodiment, the first metal layer M1 includes the first signal line L1, the second metal layer M2 includes the second signal line L2, and the third metal layer M3 includes the third signal line L3. The microfluidic substrate 000 includes a plurality of binding parts BP on the second electrode layer 50. The third signal line L3 is connected to a bonding part BP through a sixth via hole K6.

The embodiment explains that drive signals and power signals required by each detection unit 00 in the microfluidic substrate 000 can be provided by an external drive circuit. For example, various signals required by the microfluidic substrate 000 can be provided by binding external driving circuits such as driver chips or flexible circuit boards on the microfluidic substrate 000. In the embodiment, the first signal line L1 of the first metal layer M1, the second signal line L2 of the second metal layer M2, and the third signal line L3 of the third metal layer M3 can be in a frame area of the microfluidic substrate 000 where an external driving circuit is bound, for realizing a transmission of a driving signal provided by an external driving circuit such as a driver chip or a flexible circuit board to an area where the detection unit 00 is located by using a wire-changing structure of the peripheral wiring. In the embodiment, the microfluidic substrate 000 is set to include a plurality of binding parts BP that can be in a peripheral frame area of the microfluidic substrate 000, or another area that does not affect a function of the detection unit 00. A binding part BP is on the second electrode layer 50, that is, a material of the second electrode layer 50 can be used to form each binding part BP. The third signal line L3 is connected to the binding part BP through the sixth via hole K6, thereby realizing that a driving signal provided by an external driving circuit such as a driver chip or a flexible circuit board bound to a position of the binding part BP of the second electrode layer 50, by using wire-changing structures of the first signal line L1 of the first metal layer M1, the second signal line L2 of the second metal layer M2, and the third signal line L3 of the third metal layer, is transmitted to the area where the detection unit 00 is located, which provides a driving signal for the detection unit 00 to ensure a detection function of each detection unit 00.

Some optional embodiments can be referred to FIG. 1, FIG. 7 and FIG. 11. FIG. 11 illustrates another cross-sectional view of the detection unit in FIG. 7. In one embodiment, the third metal layer M3 further includes a first protection part 203 between the photosensitive element array layer 30 and the second switch transistor T2. A drain T2D of the second switch transistor T2 is electrically connected to the photosensitive element PD through the first protection part 203.

The embodiment explains that, while the third metal layer M3 arranged with the bias voltage part PB is on the side of the second metal layer M2 away from the base 10 and is between the photosensitive element array layer 30 and the second metal layer M2, the first protection part 203 on the third metal layer M3 may be arranged between the photosensitive element array layer 30 and the second switch transistor T2. Optionally, the first protection part 203 and the bias voltage part PB of the third metal layer M3 connected to a common voltage signal may be independent and insulated from each other, which is configured for the drain T2D of the second switch transistor T2 serving as a switching element of the photosensitive element PD to be electrically connected to the photosensitive element PD through the first protection part 203. If the first protection part 203 is not arranged, when a surface of the photosensitive element PD facing the base 10 is directly connected to the drain T2D of the second switch transistor T2, during a photolithography process of other patterned structures of the third metal layer M3, a surface of the drain T2D of the second switch transistor T2 of the second metal layer M2 facing away from the base 10 is exposed, and is vulnerable to the photolithography process, thereby affecting a performance of the second switch transistor T2. Therefore, in the embodiment, the first protection part 203 is arranged between the photosensitive element array layer 30 and the second switch transistor T2, and the drain T2D of the second switch transistor T2 is electrically connected to the photosensitive element PD through the first protection part 203, which can protect the drain T2D of the second switch transistor T2 and is conductive to ensuring a performance of the second switch transistor T2.

Optionally, as shown in FIG. 11, the first protection part 203 is electrically connected to the side of the photosensitive element PD facing the base 10. Since the first protection part 203 of the third metal layer M3 and the photosensitive element PD are both conductive structures, the drain T2D of the second switch transistor T2 is electrically connected to the photosensitive element PD through the first protection part 203, so that the first protection part 203 is in direct contact with the side of the photosensitive element PD facing the base 10. Further optionally, the first protection part 203 may be in direct contact with the N-type semiconductor portion PD1 on the side of the photosensitive element PD facing the base 10, to realize an electrical connection between the drain T2D of the second switch transistor T2 and the photosensitive element PD, which is also conductive to reducing a thickness of an insulating layer in the substrate and realize a thinner design of the substrate.

Some optional embodiments can be referred to FIG. 1, FIG. 7 and FIG. 11. In the direction Z perpendicular to the plane of the base 10, at least part of the bias voltage part PB overlaps an active part T1P of the first switch transistor T1. At least part of the bias voltage part PB overlaps an active part T2P of the second switch transistor T2.

The embodiment explains that when the third metal layer M3 arranged with the bias voltage part PB is on the side of the second metal layer M2 away from the base 10 and is between the photosensitive element array layer 30 and the second metal layer M2, at least part of the bias voltage portion PB of the third metal layer M3 can be multiplexed as a light-shielding structure, which has a better light-shielding effect on a transistor. The bias voltage part PB provides a fixed common potential, which can also make a characteristics of the transistor more stable. When a distance between the bias voltage part PB of the third metal layer M3 and a film layer where the active part T2P of the second switch transistor T2 is located and a film layer where the active part T1P of the first switch transistor T1 is located is relatively close, a capacitor is formed between the film layers where the active parts of the transistors are located, which can be understood as a top gate of a transistor. Based on a principle of top-gate modulation, if the bias voltage part PB is not connected to a fixed potential, the bias voltage part PB that is not connected to the fixed potential is prone to fluctuations, which will affect an output performance of a transistor. Therefore, in the embodiment, the bias voltage parts PB connected to a fixed potential (i.e., a common voltage signal) overlap the active parts of the transistors. Even if output performances of the transistors are affected, output offsets caused by the overlapping is fixed, thereby avoiding affecting use effects of the first switch transistor T1 and the second switch transistor T2.

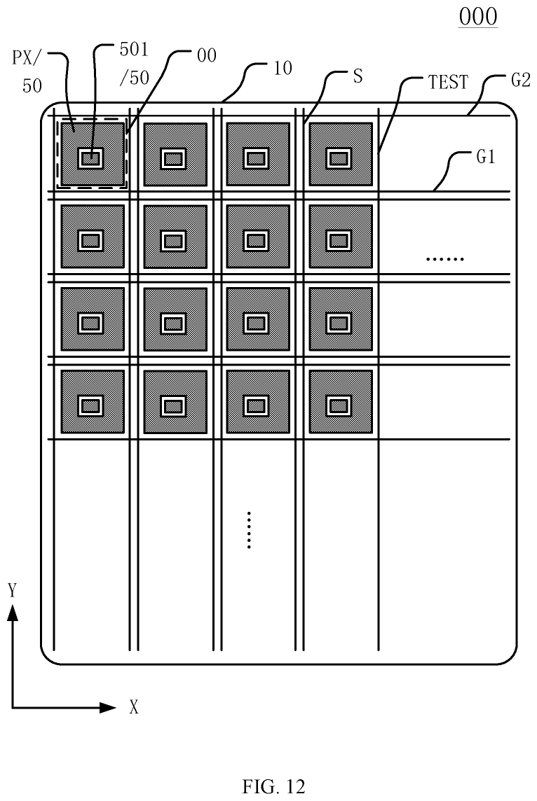

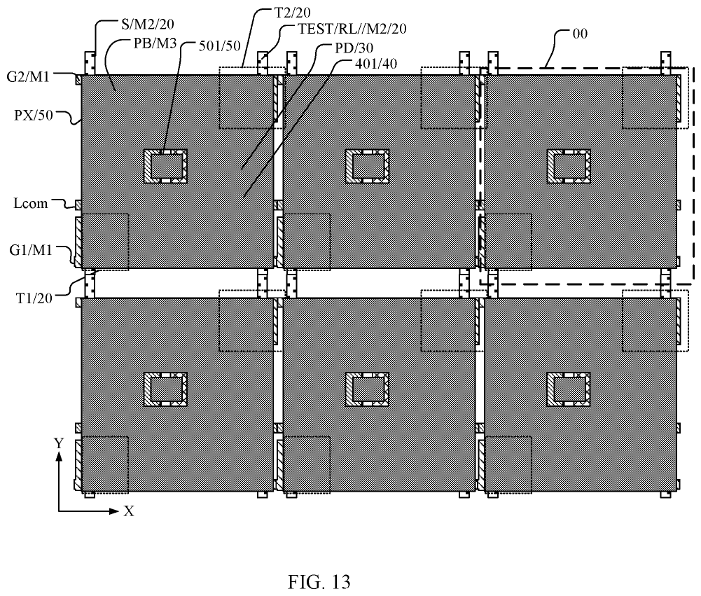

Some optional embodiments can be referred to FIG. 12 and FIG. 13. FIG. 12 illustrates another planar view of a microfluidic substrate consistent with various embodiments of the present disclosure. FIG. 13 illustrates an enlarged structural view of a local area in FIG. 12 (it can be understood that transparency is filled in FIG. 13 to clearly illustrate a structure of one embodiment). In the embodiment, the microfluidic substrate 000 includes a plurality of first scan lines G1 and a plurality of data lines S that are cross-isolated to define the area where the detection unit 00 is located. The gate of the first switch transistor T1 is electrically connected to a first scan line G1, a source of the first switch transistor T1 is electrically connected to a data line S, and the drain of the first switch transistor T1 is electrically connected to the drive electrode PX. A gate of the second switch transistor T2 is electrically connected to a second scan line G2, a source of the second switch transistor T2 is electrically connected to a detection signal line TEST, and the drain of the second switch transistor T2 is electrically connected to the side of the photosensitive element PD facing the base 10.

The embodiment explains that the microfluidic substrate 000 includes the plurality of first scan lines G1 and the plurality of data lines S that are cross-isolated to define the area where the detection unit 00 is located. The gate of the first switch transistor T1 is electrically connected to a first scan line G1, the source of the first switch transistor T1 is electrically connected to a data line S, and the drain of the first switch transistor T1 is electrically connected to the drive electrode PX. Under a control of a scanning signal provided by the first scan line G1, the first switch transistor T1 is turned on, and a data voltage signal provided by the data line S connected to the source of the first switch transistor T1 is transmitted to the drive electrode PX connected to the drain of the first switch transistor T1 to provide an electric signal for the drive electrodes PX of each detection unit 0 to drive a liquid droplet to travel. The base 10 side of the microfluidic substrate 000 may also include a plurality of second scan lines G2 and a plurality of detection signal lines TEST, the gate of the second switch transistor T2 is electrically connected to a second scan line G2, and the source of the second switch transistor T2 is electrically connected to a detection signal line TEST, the drain of the second switch transistor T2 is electrically connected to the side of the photosensitive element PD facing the base 10. Optionally, the photosensitive signal detection terminal RL of the detection unit 00 is connected to the detection signal line TEST on the microfluidic substrate 000. Under a control of a scanning signal provided by the second scan line G2, the second switch transistor T2 is turned on, and he photosensitive signal detected by the photosensitive element PD connected to the drain of the second switch transistor T2 is transmitted to the detection signal line TEST connected to the source of the second switch transistor T2 and is outputted to realize a photodetection function of the detection unit 00.

Optionally, in one embodiment, the first scan line G1 and the second scan line G2 correspondingly connected to the detection unit 00 extend along a first direction X. Along a second direction Y, the first scan line G1 and the second scan line G2 of the detection unit 00 are respectively on opposite sides of the detection unit 00. The first direction X intersects the second direction Y. In the embodiment, the first direction X and the second direction Y being perpendicular to each other is taken as an example for illustration. Along the first direction X, the data line S and the detection signal line TEST of the detection unit 00 are respectively on opposite sides of the detection unit 00, to reasonably utilize a space between adjacent detection units 00 to arrange the above signal routing. It can be understood that a same row of detection units 00 in the embodiment may share one first scan line G1 and one second scan line G2, and a same column of detection units 00 may share one data line S and one detection signal line TEST. During specific implementation, other setting methods may also be used. Optionally, the first scan lines G1 and the second scan lines G2 in the embodiment can be arranged on the first metal layer M1, the data lines S and the detection signal lines TEST can be arranged on the second metal layer M2, or other metal film layers may be used to arrange the above signal lines, which is not limited herein.

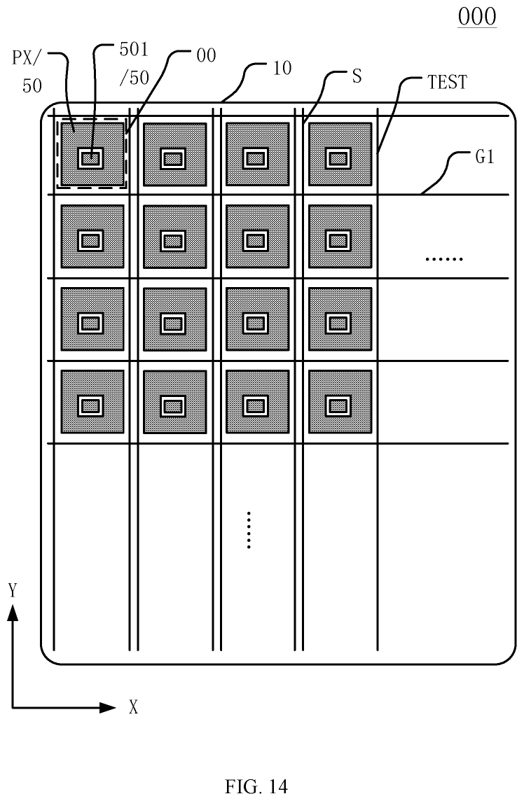

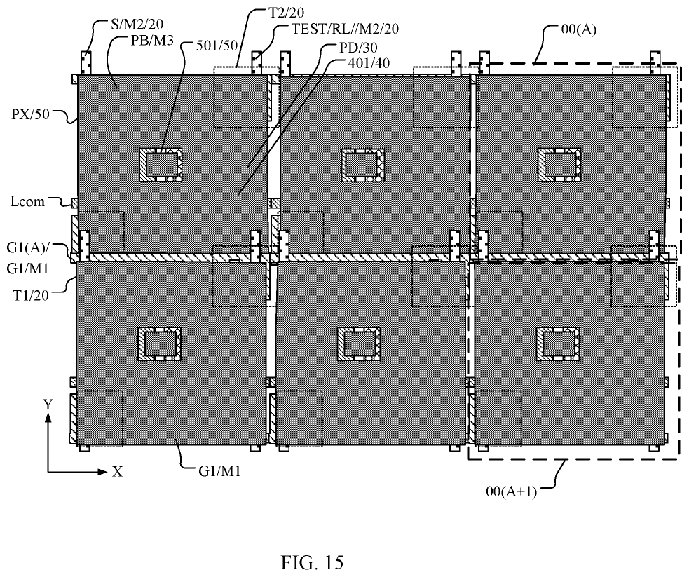

Some optional embodiments can be referred to FIG. 14 and FIG. 15. FIG. 14 illustrates another planar view of a microfluidic substrate consistent with various embodiments of the present disclosure. FIG. 15 illustrates an enlarged structural view of a local area in FIG. 14 (it can be understood that transparency is filled in FIG. 15 to clearly illustrate a structure of one embodiment). In the embodiment, a plurality of detection units 00 are arranged along the first direction X to form a detection unit row OOH, and a plurality of detection unit rows OOH is arranged along the second direction Y. The first direction X intersects the second direction Y. The microfluidic substrate 000 includes a plurality of first scan lines G1 and a plurality of data lines S that are cross-isolated to define the area where the detection unit 00 is located, the first scan lines G1 extend along the first direction X, and the data line S extends along the second direction Y. Along the second direction Y, the gate of the first switch transistor T1 corresponding to the detection unit 00 (A) in the A-th row is connected to the first scan line G1 (A) in the A-th row, and the source of the first switch transistor T1 is connected to the data The line S is connected, and the drain of the first switch transistor T1 is connected to the drive electrode PX. Along the second direction Y, the gate of the second switch transistor T2 corresponding to the detection unit 00 (A+1) in the A+1th row is connected to the A-th first scan line G1 (A), and the gate of the second switch transistor T2. The source of the second switch transistor T2 is connected to the detection signal line TEST, and the drain of the second switch transistor T2 is connected to the photosensitive element PD, and A is a positive integer.

The embodiment explains that the microfluidic substrate 000 includes a plurality of first scan lines G1 and a plurality of data lines S, and the first scan lines G1 and data lines S are cross insulated to define the area where the detection unit 00 is located. The gate of the first switch transistor T1 is electrically connected to the first scan line G1, the source of the first switch transistor T1 is electrically connected to the data line S, and the drain of the first switch transistor T1 is electrically connected to the drive electrode PX. Under the control of the scanning signal provided by the first scan line G1, the first switch transistor T1 is turned on. The data voltage signal provided on the data line S connected to the source of the first switch transistor T1 is transmitted to the drive electrode PX connected to the drain of the first switch transistor T1 to provide driving droplets for the drive electrodes PX of each detection unit 00 traveling electrical signal. In the embodiment, along the second direction Y, the gate of the first switch transistor T1 corresponding to the detection unit 00 (A) in the A-th row is connected to the A-th first scan line G1 (A). The source of the first switch transistor T1 is connected to the data line S, and the drain of the first switch transistor T1 is connected to the drive electrode PX, that is, a gate control signal of the first switch transistor T1 of the detection unit 00 (A) in the A-th row is controlled by the first scan line G1 (A) in the A-th row. Along the second direction Y, the gate of the second switch transistor T2 corresponding to the detection unit 00 (A+1) in the (A+1)-th row is connected to the A-th first scan line G1 (A), and the source of the second switch transistor T2 is connected to the detection signal line TEST. That is, a gate control signal of the second switch transistor T2 of the detection unit 00 (A+1) in the (A+1)-th row is also controlled by the A-th first scan line G1 (A), so that the scanning signal of the first switch transistor T1 of the detection unit 00 in a current row is multiplexed with the scanning signal of the second switch transistor T2 of the detection unit 00 in a next row. The first scan line G1 driving the first switch transistor T1 in the A-th row synchronously drives the second switch transistor T2 in the (A+1) row. While a liquid droplet in the detection unit 00 in the A-th row is driven, the photosensitive detection is performed on the detection unit 00 in the (A+1)-th row. The photosensitive signal detection terminal RL of the detection unit 00 is connected to the detection signal line TEST on the microfluidic substrate 000. Under a control of a scanning signal provided by the first scan line G1 (A) in the A-th row, the second switch transistor T2 in the (A+1)-th row is turned on, a photosensitive signal detected by the photosensitive element PD connected to the drain of the second switch transistor T2 in the (A+1)-th row is transmitted to the detection signal line TEST connected to the source of the second switch transistor T2 and is outputted to realize a photosensitive detection function of the detection unit 00 in the (A+1)-th row. Therefore, a liquid droplet traveling and a photosensitive detection on the substrate can be driven simultaneously, and number of scanning signal lines on the substrate can be greatly reduced, which is conductive to providing more space for the substrate to arrange detection units 00 and improving a detection effect.

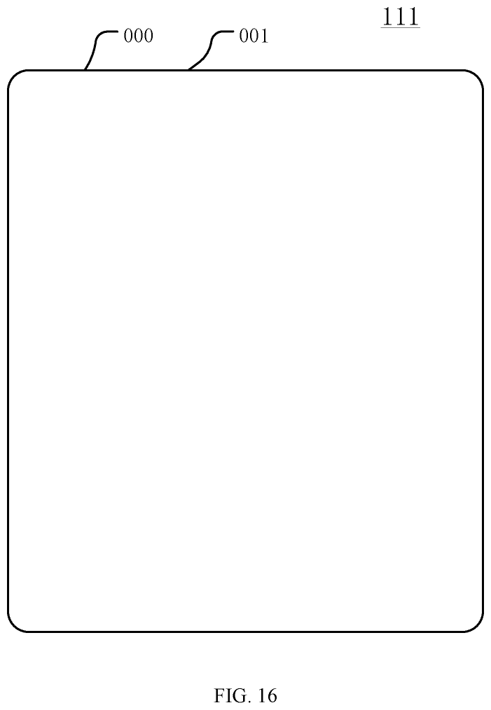

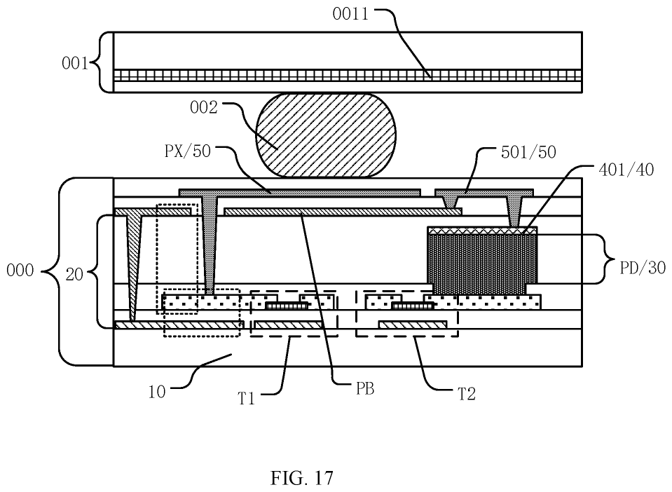

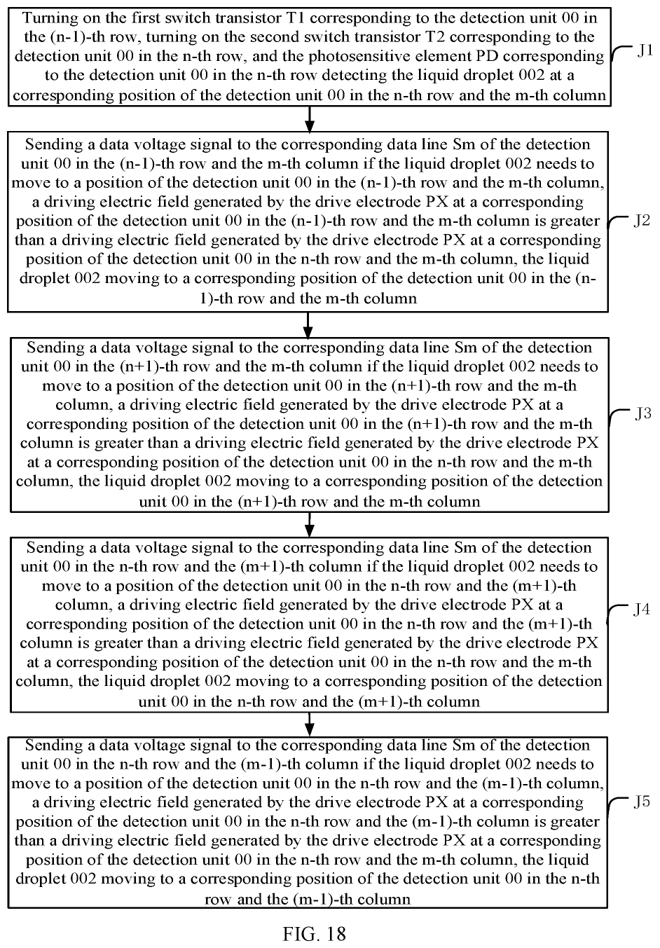

Some optional embodiments can be referred to FIG. 16 and FIG. 17. FIG. 16 illustrates a planar view of a microfluidic device consistent with various embodiments of the present disclosure. FIG. 17 illustrates a partial cross-sectional view of the microfluidic device in FIG. 16. In one embodiment, a microfluidic device 111 includes the microfluidic substrate 000 provided in the above embodiments, a second substrate 001 opposite to the microfluidic substrate 000, and a liquid droplet 002 between the second substrate 001 and the microfluidic substrate 000. Optionally, a side of the second substrate 001 facing the microfluidic substrate 000 and the side of the microfluidic substrate 000 facing the second substrate 001 may further include a hydrophobic layer to realize a control function of a liquid droplet of the microfluidic device 111. The microfluidic device 111 has beneficial effects of the microfluidic substrate 000 provided in the above embodiments. For details, reference may be made to specific descriptions of the microfluidic substrate 000 in the above embodiments, which is not repeated herein.

Optionally, as shown in FIG. 16 and FIG. 17, the side of the second substrate 001 facing the microfluidic substrate 000 includes a third electrode layer 0011. Further optionally, the third electrode layer 0011 is connected to a fixed DC potential signal, such as a ground signal. The third electrode layer 0011 can be arranged on an entire surface of the second substrate 001 facing the microfluidic substrate 000, and a driving electric field for driving a movement of the liquid droplet 002 is formed between the third electrode layer 0011 and the drive electrodes PX of each detection unit 00. By setting voltage signals on the drive electrodes PX of different detection units 00 to be different, electric fields formed between the third electrode layers 0011 and the drive electrodes PX of adjacent detection units 00 can be different, so that the liquid droplet 002 travels toward a position with a strong electric field, thereby realizing an effect of the liquid droplet 002 traveling between the second substrate 001 and the microfluidic substrate 000 of the microfluidic device 111.

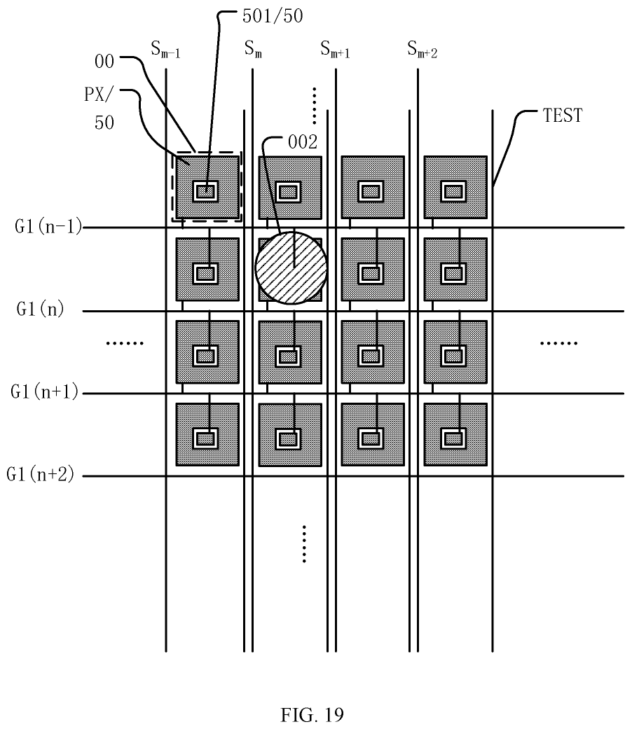

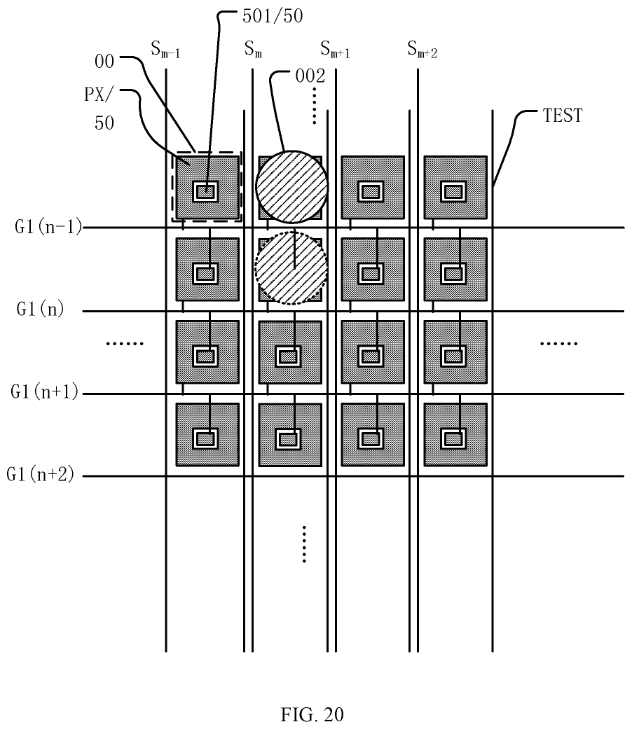

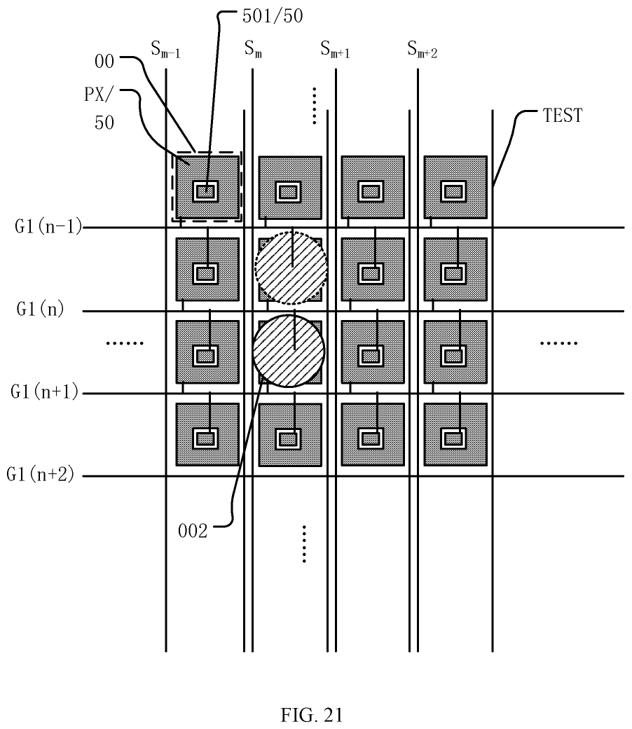

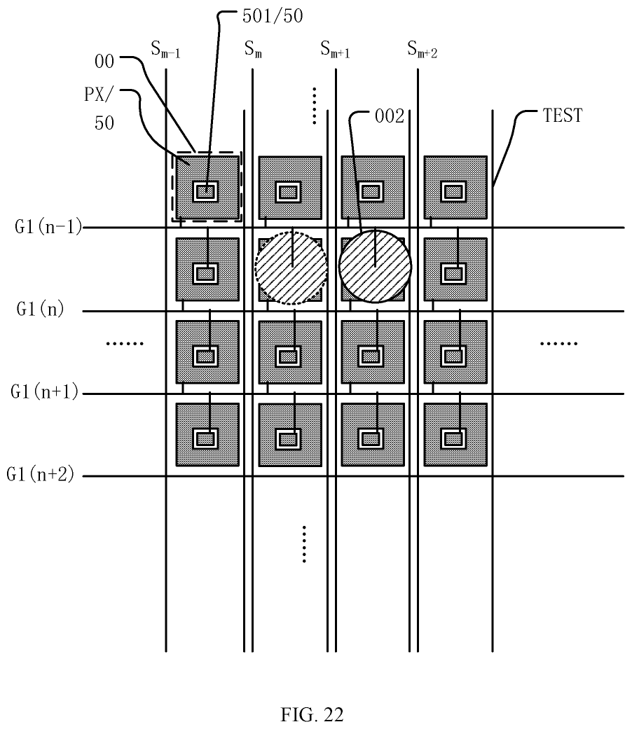

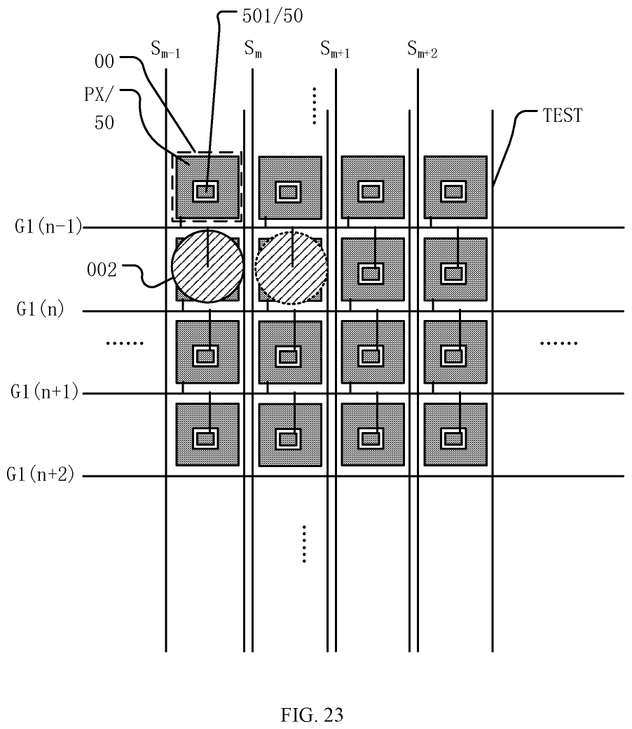

Some optional embodiments can be referred to FIGS. 14-17 and FIGS. 18-23. FIG. 18 illustrates a flow chart of a driving method of a microfluidic device consistent with various embodiments of the present disclosure. FIG. 19 illustrates a schematic diagram of a travel and detection of a liquid droplet in FIG. 18. FIG. 20 illustrates another schematic diagram of the travel and detection of the liquid droplet in FIG. 18. FIG. 21 illustrates another schematic diagram of the travel and detection of the liquid droplet in FIG. 18. FIG. 22 illustrates another schematic diagram of the travel and detection of the liquid droplet in FIG. 18. FIG. 23 illustrates another schematic diagram of the travel and detection of the liquid droplet in FIG. 18 (it can be understood that transparency is filled in FIGS. 19-23 to clearly illustrate a structure of one embodiment). In the embodiment, a driving method of a microfluidic device is used to drive the above microfluidic device 111 to perform droplet traveling and detection. The driving method includes the following steps.

J1: turning on the first switch transistor T1 corresponding to the detection unit 00 in the (n−1)-th row, turning on the second switch transistor T2 corresponding to the detection unit 00 in the n-th row, and the photosensitive element PD corresponding to the detection unit 00 in the n-th row detecting the liquid droplet 002 at a corresponding position of the detection unit 00 in the n-th row and the m-th column, i.e., a position of the liquid droplet 002 shown in FIG. 19.

J2: sending a data voltage signal to the corresponding data line Sm of the detection unit 00 in the (n−1)-th row and the m-th column if the liquid droplet 002 needs to move to a position of the detection unit 00 in the (n−1)-th row and the m-th column, a driving electric field generated by the drive electrode PX at a corresponding position of the detection unit 00 in the (n−1)-th row and the m-th column is greater than a driving electric field generated by the drive electrode PX at a corresponding position of the detection unit 00 in the n-th row and the m-th column, the liquid droplet 002 moving to a corresponding position of the detection unit 00 in the (n−1)-th row and the m-th column, i.e., a position of the liquid droplet 002 shown in FIG. 20, the liquid drop shown by a solid line in FIG. 20 representing a position of the liquid drop after moving, and the liquid drop shown by a dotted line in FIG. 20 representing a position of the liquid drop before moving.

J3: sending a data voltage signal to the corresponding data line Sm of the detection unit 00 in the (n+1)-th row and the m-th column if the liquid droplet 002 needs to move to a position of the detection unit 00 in the (n+1)-th row and the m-th column, a driving electric field generated by the drive electrode PX at a corresponding position of the detection unit 00 in the (n+1)-th row and the m-th column is greater than a driving electric field generated by the drive electrode PX at a corresponding position of the detection unit 00 in the n-th row and the m-th column, the liquid droplet 002 moving to a corresponding position of the detection unit 00 in the (n+1)-th row and the m-th column, i.e., a position of the liquid droplet 002 shown in FIG. 21, the liquid drop shown by a solid line in FIG. 21 representing a position of the liquid drop after moving, and the liquid drop shown by a dotted line in FIG. 21 representing a position of the liquid drop before moving.

J4: sending a data voltage signal to the corresponding data line Sm of the detection unit 00 in the n-th row and the (m+1)-th column if the liquid droplet 002 needs to move to a position of the detection unit 00 in the n-th row and the (m+1)-th column, a driving electric field generated by the drive electrode PX at a corresponding position of the detection unit 00 in the n-th row and the (m+1)-th column is greater than a driving electric field generated by the drive electrode PX at a corresponding position of the detection unit 00 in the n-th row and the m-th column, the liquid droplet 002 moving to a corresponding position of the detection unit 00 in the n-th row and the (m+1)-th column, i.e., a position of the liquid droplet 002 shown in FIG. 22, the liquid drop shown by a solid line in FIG. 22 representing a position of the liquid drop after moving, and the liquid drop shown by a dotted line in FIG. 22 representing a position of the liquid drop before moving.

J5: sending a data voltage signal to the corresponding data line Sm of the detection unit 00 in the n-th row and the (m−1)-th column if the liquid droplet 002 needs to move to a position of the detection unit 00 in the n-th row and the (m−1)-th column, a driving electric field generated by the drive electrode PX at a corresponding position of the detection unit 00 in the n-th row and the (m−1)-th column is greater than a driving electric field generated by the drive electrode PX at a corresponding position of the detection unit 00 in the n-th row and the m-th column, the liquid droplet 002 moving to a corresponding position of the detection unit 00 in the n-th row and the (m−1)-th column, i.e., a position of the liquid droplet 002 shown in FIG. 23, the liquid drop shown by a solid line in FIG. 23 representing a position of the liquid drop after moving, and the liquid drop shown by a dotted line in FIG. 23 representing a position of the liquid drop before moving, wherein m and n are positive integers greater than or equal to 2.

Optionally, in one embodiment, each detection unit 00 also includes the photosensitive element PD, through which can detect whether the liquid droplet has moved to a range of the detection unit 00 at a desired position. If an output result of an optical signal detected by the photosensitive element PD is that the liquid droplet 002 has not moved to the desired position, the moving can continue to be repeated. For example, the liquid droplet 002 needs to move from a corresponding position of the detection unit 00 in the n-th row and the m-th column to a position of the detection unit 00 in the (n−1)-th row and the m-th column. When a data voltage signal is send to the corresponding data line Sm of the detection unit 00 in the (n−1)-th row and the m-th column, the first scan line G1 (n−1) in the (n−1)-th row and the m-th column controls the first switch transistor T1 in the (n−1)-th row and the m-th column to be turned on, so that a driving electric field generated at a corresponding position of the drive electrode PX of the detection unit 00 in the (n−1)-th row and the m-th column is greater than a driving electric field generated at a corresponding position of the drive electrode PX of the detection unit 00 in the n-th row and the m-th column. At a same time, the first scan line G1 (n−1) in the (n−1)-th row and the m-th column controls the corresponding second switch transistor T2 of the detection unit 00 in the n-th row and the m-th column to be turned on. The photosensitive element PD in the n-th row and m-th column can detect a corresponding position of the detection unit 00 in the n-th row and m-th column. If the photosensitive element PD detects a change in a photocurrent signal, the change means that the liquid droplet 002 has moved to a corresponding position of the detection unit 00 in the (n−1)-th row and the m-th column. If the corresponding photosensitive element PD of the detection unit 00 in the n-th row and the m-th column does not detect a change in the photocurrent signal, the change means that the liquid droplet 002 is still in the corresponding position of the detection unit 00 in the n-th row and the m-th column, data voltage signals can be repeatedly input to the corresponding data line Sm of the detection unit 00 in the (n−1)-th row and the m-th column, so that a driving electric field generated by the drive electrode PX at a corresponding position of the detection unit 00 in the (n−1)-th row and the m-th column is greater than a driving electric field generated by the drive electrode PX at a corresponding position of the detection unit 00 in the n-th row and the m-th column, the liquid droplet 002 is driven to travel until the corresponding photosensitive element PD of the detection unit 00 in the n-th row and the m-th column cannot detect the liquid droplet 002, and a next step of traveling operation is performed. In the embodiment, the driving method of the microfluidic device provided can feed back a position of the liquid droplet in real time during a moving process of the liquid droplet to accurately control a travel of the liquid droplet.

As disclosed, the microfluidic substrate, the microfluidic device, and the driving method thereof provided by the present disclosure at least achieve the following beneficial effects.

The microfluidic substrate provided by the present disclosure can be configured to control a flow position of a tiny liquid droplet by setting electric field intensities in different areas on the substrate by using an electrowetting principle to realize driving of the tiny liquid droplet. The microfluidic substrate includes a plurality of detection units arranged in an array, and a detection units at least includes a first switch transistor, a second switch transistor, a drive electrode and a photosensitive element that are electrically connected. The drive electrode can be configured to provide a voltage/electric field to drive the tiny liquid droplet, and the photosensitive element can be configured to optically detect the tiny liquid droplet to analyze a fluorescence intensity and a corresponding droplet composition, or during a movement of the liquid droplet, a position of the liquid droplet is fed back in real time through an optical detection of the photosensitive element to precisely control a path of the liquid droplet. The second electrode layer arranged in the present disclosure further includes a plurality of connection parts, and the connection part and the drive electrode in the detection unit are insulated from each other, that is, although the connection part and the drive electrode are both on the second electrode layer, the connection part and the drive electrode in a same detection unit are mutually independent structures. Through the connection part, a common voltage signal provided by the bias voltage part connected to the connection part is transmitted as a bias voltage signal of the photosensitive element to the first electrode terminal on the side of the photosensitive element away from the substrate, so that a light-sensing element receives the bias voltage signal to realize a light-sensing function thereof when sensing. The bias voltage part can not only provide a bias voltage signal for the photosensitive element through the connection part, but also can be configured to overlap the drive electrode to form a storage capacitor to drive the liquid droplet to travel, thereby reducing an area occupied by signal wires and capacitors in a single detection unit 00, and increasing a photoelectric detection area of the photosensitive element PD in the single detection unit 000, which is conductive to ensuring a sensing effect of the photosensitive element. When a capacitance value required by the detection unit remains unchanged, an overall area of the storage capacitor occupied by the detection unit 00 can be reduced, which is conductive to increasing an available area of the photosensitive element in the detection unit, increasing an intensity of the detectable photosensitive detection signal, improving an efficiency and accuracy of optical detection, and realizing a high-density and high-precision photoelectric detection.

Although some specific embodiments of the present disclosure have been described in detail by way of examples, a person skilled in the art should understand that the above examples are for illustration only and are not intended to limit the scope of the present disclosure. The above embodiments can be modified by a person skilled in the art without departing from the scope and spirit of the present disclosure. The protection scope of the present disclosure is limited by appended claims.

What is claimed is:

1. A microfluidic substrate, comprising a plurality of detection units arranged in an array, a detection unit of the plurality of detection units at least including a first switch transistor, a second switch transistor, a drive electrode, and a photosensitive element, wherein the microfluid substrate comprises:
a base;
a transistor array layer on a side of the base, first switch transistors and second switch transistors being on the transistor array layer;
a photosensitive element array layer on a side of the transistor array layer away from the substrate, photosensitive elements being on the photosensitive element array layer, and the second switch transistors being electrically connected to a side of the photosensitive elements facing the base;
a first electrode layer on a side of the photosensitive element array layer away from the base, the first electrode layer including a plurality of first electrode terminals electrically connected to a side of the photosensitive elements away from the base;
a second electrode layer on a side of the first electrode layer away from the base, drive electrodes being on the second electrode layer, and first switch transistors being electrically connected to the drive electrodes;
the second electrode layer further including a plurality of connection parts, in one detection unit of the plurality of detection units, a connection part of plurality of connection parts the being insulated from a drive electrode, and a first electrode terminal of the plurality of first electrode terminals being connected to a bias voltage part through the connection part; and
a film layer where the bias voltage part is located is on a side of the second electrode layer facing the base.

2. The microfluidic substrate according to claim 1, wherein:
the photosensitive element includes an N-type semiconductor part, an intrinsic semiconductor part and a P-type semiconductor part arranged in a stack, and the intrinsic semiconductor part is between the N-type semiconductor part and the P-type semiconductor part;
the N-type semiconductor part is connected to a drain of the second switch transistor;
the P-type semiconductor part is electrically connected to the first electrode terminal;
the connection part is connected to the first electrode terminal through a first via hole, and the connection part is connected to the bias voltage part through a second via hole; and
the first via hole and the second via hole are formed in same steps and in a same process.

3. The microfluidic substrate according to claim 1, wherein the bias voltage part is connected to a bias voltage signal line, the bias voltage part is arranged on a same layer as the bias voltage signal line, and the bias voltage signal line is connected to a common voltage signal.

4. The microfluidic substrate according to claim 1, wherein the detection unit includes a storage capacitor, a first electrode of the storage capacitor is connected to the bias voltage unit, and a second electrode of the storage capacitor is connected to the drive electrode.

5. The microfluidic substrate according to claim 4, wherein:
the storage capacitor includes at least a first storage capacitor;
the transistor array layer includes at least a first metal layer and a second metal layer, the first metal layer includes a plurality of first parts, and a drain of the first switch transistor is on the second metal layer;
the bias voltage part is on the third metal layer, and the third metal layer is on a side of the transistor array layer away from the second metal layer; and
in a direction perpendicular to a plane where the base is located, a first part of the plurality of first parts overlaps a drain of the first switch transistor to form the first storage capacitor.

6. The microfluidic substrate according to claim 5, wherein:
the storage capacitor also includes a second storage capacitor;
the third metal layer includes second parts, and a second part is connected to the first part through a third via hole; and
in a direction perpendicular to the plane where the base is located, the second part overlaps the drain of the first switch transistor to form the second storage capacitor.

7. The microfluidic substrate according to claim 5, wherein:
the storage capacitor also includes a third storage capacitor; and
in a direction perpendicular to the plane where the base is located, the bias voltage part overlaps the drive electrode to form the third storage capacitor.

8. The microfluidic substrate according to claim 5, wherein:
the storage capacitor also includes a fourth storage capacitor; and
in a direction perpendicular to the plane where the base is located, the first electrode terminal overlaps the drive electrode to form the fourth storage capacitor.

9. The microfluidic substrate according to claim 5, wherein the third metal layer is between the first electrode layer and the second electrode layer.

10. The microfluidic substrate according to claim 5, wherein the third metal layer is between the photosensitive element array layer and the transistor array layer.

11. The microfluidic substrate according to claim 10, wherein:
the first metal layer includes a first signal line, the second metal layer includes a second signal line, and the third metal layer includes a third signal line;
the third signal line is connected to the second signal line through a fourth via hole, and the third signal line is connected to the first signal line through a fifth via hole; and
the fourth via hole and the fifth via hole are formed in same steps and in a same process.

12. The microfluidic substrate according to claim 11, wherein:
the microfluidic substrate includes a plurality of binding parts on the second electrode layer; and
the third signal line is connected to a binding part of the plurality of binding parts through a sixth via hole.

13. The microfluidic substrate according to claim 10, wherein:
the third metal layer further includes a first protection part between the photosensitive element array layer and a second switch transistor; and
a drain of the second switch transistor is electrically connected to the photosensitive element through the first protection part.

14. The microfluidic substrate according to claim 13, wherein the first protection part is electrically connected to a side of the photosensitive element facing the base.

15. The microfluidic substrate according to claim 10, wherein:
in a direction perpendicular to the plane where the base is located, at least part of the bias voltage part overlaps an active part of the first switch transistor; and at least part of the bias voltage part overlaps an active part of the second switch transistor.

16. The microfluidic substrate according to claim 1, comprising a plurality of first scan lines and a plurality of data lines cross-insulated to define an area where the plurality of detection unit is located, wherein:
a gate of the first switch transistor is electrically connected to a first scan line of the plurality of first scan lines, a source of the first switch transistor is electrically connected to a data line of the plurality of data lines, and a drain of the first switch transistor is electrically connected to the drive electrode; and
a gate of the second switch transistor is electrically connected to a second scan line, a source of the second switch transistor is electrically connected to a detection signal line, and a drain of the second switch transistor is electrically connected to a side of the photosensitive element facing the base.

17. The microfluidic substrate according to claim 16, wherein:
the first scan line and the second scan line extend along a first direction; and
along a second direction, the first scan line and the second scan line of one detection unit are respectively on opposite sides of the detection unit, and the first direction intersects the second direction.

18. The microfluidic substrate according to claim 1, wherein:
a plurality of detection units is arranged along a first direction to form a detection unit row, a plurality of detection unit rows is arranged along a second direction, and the first direction intersects the second direction;
the microfluidic substrate includes a plurality of first scan lines and a plurality of data lines cross-insulated to define an area where the detection unit is located, and the plurality of first scan lines extends along the first direction, and the plurality of data lines extends along the second direction;
along the second direction, a gate of the first switch transistor corresponding to the detection unit in the A-th row is connected to the A-th first scan line, a source of the first switch transistor is connected to a data line of the plurality of data lines, and a drain of the first switch transistor is connected to the drive electrode; and
along the second direction, a gate of the second switch transistor corresponding to the detection unit in the (A+1)-th row is connected to the A-th first scan line, and a source of the second switch transistor is connected to a detection signal line, and a drain of the second switch transistor is connected to the photosensitive element, and A is a positive integer.

19. A microfluidic device, comprising a microfluidic substrate, a second substrate opposite to the microfluidic substrate, and a liquid droplet between the second substrate and the microfluidic substrate, the microfluidic substrate comprising a plurality of detection units arranged in an array, a detection unit of the plurality of detection units at least including a first switch transistor, a second switch transistor, a drive electrode, and a photosensitive element, wherein the microfluid substrate comprises:
a base;
a transistor array layer on a side of the base, first switch transistors and second switch transistors being on the transistor array layer;
a photosensitive element array layer on a side of the transistor array layer away from the substrate, photosensitive elements being on the photosensitive element array layer, and the second switch transistors being electrically connected to a side of the photosensitive elements facing the base;
a first electrode layer on a side of the photosensitive element array layer away from the base, the first electrode layer including a plurality of first electrode terminals electrically connected to a side of the photosensitive elements away from the base;
a second electrode layer on a side of the first electrode layer away from the base, drive electrodes being on the second electrode layer, and first switch transistors being electrically connected to the drive electrodes;
the second electrode layer further including a plurality of connection parts, in one detection unit of the plurality of detection units, a connection part of plurality of connection parts being insulated from a drive electrode, and a first electrode terminal of the plurality of first electrode terminals being connected to a bias voltage part through the connection part; and
a film layer where the bias voltage part is located is on a side of the second electrode layer facing the base.

20. A driving method of the microfluidic device according to claim 19, comprising:
turning on the first switch transistor corresponding to the detection unit in the (n−1)-th row, turning on the second switch transistor corresponding to the detection unit in the n-th row, and the photosensitive element detecting a liquid droplet at a corresponding position of the detection unit in the n-th row and the m-th column;
sending a data voltage signal to the corresponding data line of the detection unit in the (n−1)-th row and the m-th column if the liquid droplet needs to move to a position of the detection unit in the (n−1)-th row and the m-th column, a driving electric field generated by the drive electrode at a corresponding position of the detection unit in the (n−1)-th row and the m-th column is greater than a driving electric field generated by the drive electrode at a corresponding position of the detection unit in the n-th row and the m-th column, the liquid droplet moving to a corresponding position of the detection unit in the (n−1)-th row and the m-th column;
sending a data voltage signal to the corresponding data line of the detection unit in the (n+1)-th row and the m-th column if the liquid droplet needs to move to a position of the detection unit in the (n+1)-th row and the m-th column, a driving electric field generated by the drive electrode at a corresponding position of the detection unit in the (n+1)-th row and the m-th column is greater than a driving electric field generated by the drive electrode at a corresponding position of the detection unit in the n-th row and the m-th column, the liquid droplet moving to a corresponding position of the detection unit in the (n+1)-th row and the m-th column;
sending a data voltage signal to the corresponding data line of the detection unit in the n-th row and the (m+1)-th column if the liquid droplet needs to move to a position of the detection unit in the n-th row and the (m+1)-th column, a driving electric field generated by the drive electrode at a corresponding position of the detection unit in the n-th row and the (m+1)-th column is greater than a driving electric field generated by the drive electrode at a corresponding position of the detection unit in the n-th row and the m-th column, the liquid droplet moving to a corresponding position of the detection unit in the n-th row and the (m+1)-th column;
sending a data voltage signal to the corresponding data line of the detection unit in the n-th row and the (m−1)-th column if the liquid droplet needs to move to a position of the detection unit in the n-th row and the (m−1)-th column, a driving electric field generated by the drive electrode at a corresponding position of the detection unit in the n-th row and the (m−1)-th column is greater than a driving electric field generated by the drive electrode at a corresponding position of the detection unit in the n-th row and the m-th column, the liquid droplet moving to a corresponding position of the detection unit in the n-th row and the (m−1)-th column; and
m and n being positive integers greater than or equal to 2.

21. The driving method according to claim 20, wherein:
a side of the second substrate facing the microfluidic substrate includes a third electrode layer; and
a driving electric field driving a movement of the liquid droplet is formed between the third electrode layer and the drive electrode.
